(19) United States
(12) Patent Application Publication
(10) Pub. No.: US 2013/0258788 A1
(43) Pub. Date: Oct. 3, 2013

(54) SEMICONDUCTOR DEVICE HAVING PLURAL CHIP CONNECTED TO EACH OTHER

(71) Applicant: C/O ELPIDA MEMORY, INC., Tokyo (JP)

(72) Inventors: Akira Ide, Tokyo (JP); Naoki Ogawa, Tokyo (JP)

(73) Assignee: c/o Elpida Memory, Inc., Tokyo (JP)

(21) Appl. No.: 13/845,431

(22) Filed: Mar. 18, 2013

(30) Foreign Application Priority Data
Mar. 29, 2012 (JP) 2012-075992

(51) Int. Cl. G11C 7/10

(52) U.S. Cl. CPC G11C 7/10
USPC 365/189.05

(57) ABSTRACT

Disclosed herein is a device that includes: a first timing adjustment circuit generating a first control signal based on a command and an output buffer outputting a plurality of data sets in a serial at a timing based on the first control signal; and a second semiconductor chip including: a plurality of holding circuits holding the data sets in parallel, a second timing adjustment circuit generating a second control signal based on the command, and an input buffer sequentially capturing the data sets supplied from the holding circuits based on the second control signal.

### BACKGROUND OF THE INVENTION

1. Field of the Invention

The present invention relates to a semiconductor device and an operation timing adjustment method thereof; and particularly to a semiconductor device in which a frontend section, which has an interface function, and a backend section, which contains a memory core, are integrated on different semiconductor chips, and to an operation timing adjustment method thereof.

2. Description of Related Art

The storage capacity required for a semiconductor memory device such as a DRAM (Dynamic Random Access Memory) has been increasing year after year. In order to meet such a demand, a memory device called a multi-chip package has been proposed in recent years: in the multi-chip package, a plurality of memory chips are stacked. However, each of the memory chips included in the multi-chip package has a so-called frontend section which interfaces with the outside (a memory controller, for example) because each of the memory chips itself is a usual memory chip which operates alone. Therefore, the occupied area allocatable to a memory core in each of the memory chips is limited to the area which is obtained by subtracting the occupied area for the frontend section from the total area. It is thus difficult to increase the storage capacity per a memory chip substantially.

Furthermore, there is a problem that it is difficult to speed up transistors constituting the frontend section because the frontend section and the backend section including the memory core are produced simultaneously despite the circuits constituting the frontend section belong to a so-called logic circuits.

As a solution to such problems, a method to configure a semiconductor device by integrating the frontend section and the backend section in separate chips and stacking the chips is proposed. According to the method, it becomes possible to increase the storage capacity per a chip (per a core chip which is integrated with the backend section) because the occupied area allocatable to the memory core increases with respect to the core chip. Further, it becomes possible to configure the circuits constituting the frontend section with fast transistors because the interface chip which is integrated with the frontend section can be produced by a process different from those for the core chip. In addition, because it is also possible to allocate a plurality of core chips to an interface chip, it becomes possible to offer a high-speed semiconductor device with a very large-capacity as a whole.

As for such a semiconductor device, Japanese Patent Application Laid-Open No. 2011-081731 discloses a technique for securing a sufficient temporal margin (latch margin) for a process in which the interface chip captures read data. According to the technique, in a core chip, a replica circuit of a circuit pertaining to outputting of read data, and an output timing adjustment circuit that controls an output timing of read data are provided. In an interface chip, a process monitor circuit containing a variable delay circuit is provided. The process monitor circuit adjusts an amount of delay by the variable delay circuit in such a way that the amount of delay becomes equal to an amount of delay by the replica circuit. The result thereof is reflected in the output timing adjustment circuit. By adjusting the timing of when each of the core chips outputs read data in that manner, it becomes possible to secure a sufficient latch margin for a process in which the interface chip captures read data.

As for a SDRAM (Synchronous Dynamic Random Access Memory) of a DDR3 (Double-Data-Rate3) type, write leveling and read leveling are carried out between a memory controller and the SDRAM.

Write leveling is a process in which the memory controller adjusts a timing at which write data reach the SDRAM. During the process, first the memory controller inputs a clock signal and a data strobe signal into the SDRAM. The SDRAM samples the clock signal in synchronization with the data strobe signal and returns the results to the memory controller. The memory controller corrects the phases of the clock signal and data strobe signal based on the sampling results returned.

Read leveling is a process in which the memory controller detects a timing at which the read data are output from the SDRAM. During the process, first the memory controller issues a read command to the SDRAM. In response to the read command, the SDRAM outputs data stored in a multi-purpose register, not those stored in a memory cell array. The memory controller confirms the output timing of data that is output as described above, thereby detecting the timing at which the read data are output from the SDRAM.

However, that is not to say that all of the technique disclosed in Japanese Patent Application Laid-Open No. 2011-081731, the write leveling, and the read reveling adjust the timing with the use of actual data. Accordingly, if there is a difference between the amount of delay by a circuit that is used for timing adjustments, and the amount of delay by a circuit (actual data path) that is used for inputting and outputting of actual data, the accuracy of timing adjustment would deteriorate.

When a write operation is for example carried out in a semiconductor device of a type that uses the above-described interface chip, write data are input into an interface chip via a data input/output terminal from an external controller. The interface chip generates a control signal (referred to as “second control signal,” hereinafter) based on a write command and outputs the write data to a core chip at a timing according to the second control signal. The core chip also generates a control signal (referred to as “first control signal,” hereinafter) based on a write command and accepts the write data from the interface chip at a timing according to the first control signal.

The write data are transmitted to each core chip by the above-described mechanism. Therefore, the first control signal and the second control signal need to be in synchronization with each other. If the synchronization breaks down to a certain extent, the write operation cannot be performed properly. An allowable range for synchronization breakdown is referred to as “timing margin.”

The same could be said for the read operation. When inputting and outputting of data between chips are carried out in a conventional semiconductor device, the duration of data that are output from one semiconductor chip to another semiconductor chip is usually two clocks. As a result, the above timing margin is equal to two clocks. However, the timing margin that is equal to two clocks is not sufficient. Therefore, a semiconductor device that has a longer timing margin is desired.

### SUMMARY

In one embodiment, there is provided a semiconductor device that includes: a first semiconductor chip including: a first timing adjustment circuit generating a first control signal based on a command and an output buffer outputting a plurality of data sets in a serial at a timing based on the first control signal; and a second semiconductor chip including: a plurality of holding circuits holding the data sets in parallel, a second timing adjustment circuit generating a second control signal based on the command, and an input buffer sequentially capturing the data sets supplied from the holding circuits based on the second control signal.

In another embodiment, there is provided a semiconductor device that includes: a first semiconductor chip including a holding circuit having a data input node, the holding circuit capturing and temporarily holding data appearing on the data input node in response to a first timing signal, a buffer circuit coupled to the holding circuit, the buffer circuit outputting the data held by the holding circuit in response to a second timing signal, a first timing circuit generating one of the first and second timing signals; a second semiconductor chip includes a second timing circuit generating the other one of the first and second timing signals; and a latch circuit holding a control data that are used to adjust a gap between a timing at which the first timing signal is brought to an active level and a timing at which the second timing signal is brought to an active level.

In still another embodiment, there is provided a semiconductor device that includes: a first chip including a FIFO circuit connected to an input node thereof; and a second chip supplying an input data to the input node of the FIFO circuit. The first and second chips are stacked to each other.

According to the present invention, the delay adjustment circuit can be set to the amount of delay detected by the actual data path. Therefore, the timing at which the input buffer (input circuit) captures data can be accurately adjusted. Moreover, a plurality of holding circuits are provided in the first semiconductor chip. Therefore, at the entrance of the first semiconductor chip, the data can be held for a long period of time (which is longer than the duration of data that are output from the second semiconductor chip to the first semiconductor chip). Accordingly, the timing margin, which represents the allowable range for synchronization breakdown between the first control signal and the second control signal, can be extended compared with a conventional semiconductor device that includes no holding circuit.

Moreover, because a determination is made as to whether or not the first semiconductor chip has properly captured data and a timing for generating the first control signal is set based on the result of the determination, the timing at which the first semiconductor chip captures data can be accurately adjusted.

### BRIEF DESCRIPTION OF THE DRAWINGS

FIG. 1 is a schematic cross-sectional view explicative of a structure of a semiconductor device according to an embodiment of the present invention;

FIG. 2 is a cross-sectional view indicative of a structure of a penetrating electrode TSV1 being a sort of the penetrating electrodes TSV shown in FIG. 1;

FIG. 3 is a cross-sectional view indicative of a structure of a penetrating electrode TSV2 being a sort of the penetrating electrodes TSV shown in FIG. 1;

FIG. 4 is a cross-sectional view indicative of a modification of the structure of a penetrating electrode TSV2 being a sort of the penetrating electrodes TSV shown in FIG. 1;

FIG. 5 is a cross-sectional view indicative of a structure of a top-surface bump FBa shown in FIG. 1;

FIG. 6 is a diagram showing the relation of connection between the semiconductor device and an external memory controller according to the embodiment of the present invention;

FIG. 7 is a block diagram showing the configuration for an operation (read operation) to read data from a memory cell of the configuration of the semiconductor device according to a first preferred embodiment of the present invention;

FIG. 8 is a block diagram showing the configuration for an operation (write operation) to write data to a memory cell of the configuration of the semiconductor device according to the first preferred embodiment of the present invention;

FIG. 9 is a diagram showing an operation timing of each signal pertaining to the read operation;

FIG. 10 is a diagram showing an operation timing of each signal pertaining to the write operation;

FIG. 11 is a block diagram showing the configuration for the read operation of the configuration of the semiconductor device 10 according to a second preferred embodiment of the present invention;

FIG. 12 is a block diagram showing the configuration for the write operation of the configuration of the semiconductor device according to the second preferred embodiment of the present invention;

FIG. 13A is a diagram showing the circuit configuration of the determination margin adjustment circuit and the expectation value determination circuit shown in FIG. 11 in detail;

FIG. 13B is a diagram showing the circuit configuration of the determination margin adjustment circuit and the expectation value determination circuit shown in FIG. 12 in detail;

FIGS. 14, 15, and 16 are diagrams showing an operation timing of each signal pertaining to the read operation; and

FIGS. 17, 18, and 19 are diagrams showing an operation timing of each signal pertaining to the write operation.

### DETAILED DESCRIPTION OF THE EMBODIMENTS

Preferred embodiments of the present invention will be explained below in detail with reference to the accompanying drawings. The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessarily mutually exclusive, as some disclosed embodiments can be combined with one or more other disclosed embodiments to form new embodiments.

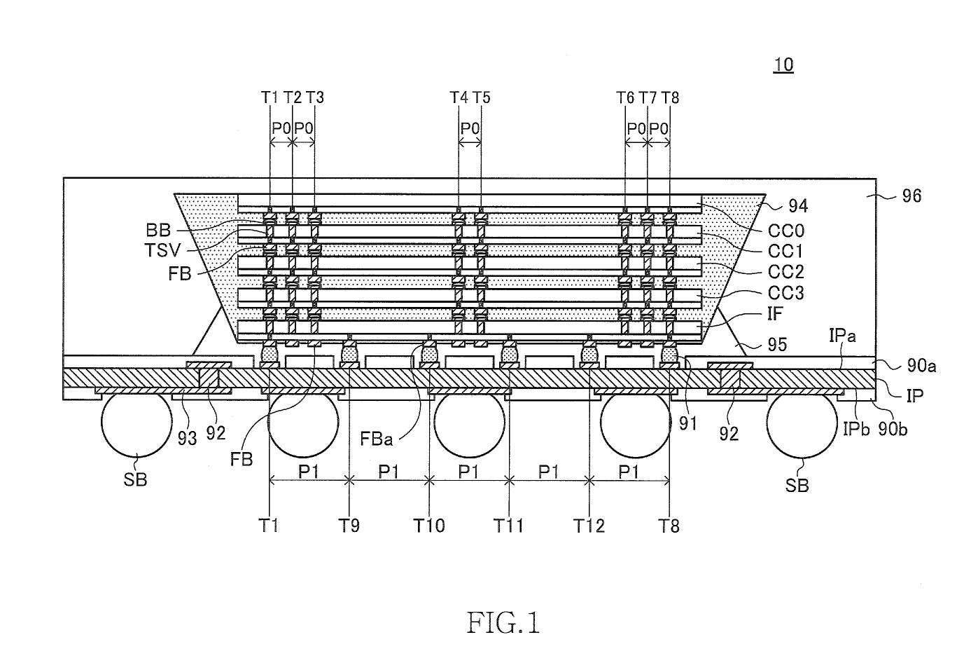

Referring now to FIG. 1, the semiconductor device 10 of the embodiment has a structure in which the following components are stacked: four core chips CC0 to CC3, which have the same functions and are produced with the use of the same production mask; one interface chip IF, which is produced with the use of a different production mask from that of the core chips CC0 to CC3; and one interposer IP. The core chips CC0 to CC3 and the interface chip IF are semiconductor chips for which a silicon substrate is used, and are stacked by a face-down method on the interposer IP. The face-down method means a method of mounting semiconductor chips in such a way that principal surfaces on which electronic circuits such as transistors are formed face downward, or that the principal surfaces face the interposer IP's side.

However, the semiconductor device of the present invention is not limited to the above structure. The semiconductor chips each may be stacked by a face-up method. The face-up method means a method of mounting semiconductor chips in such away that principal surfaces on which electronic circuits such as transistors are formed face upward, or that the principal surfaces face a side opposite to the interposer IP's side. Alternatively, the semiconductor chips stacked by the face-down method, and the semiconductor chips stacked by the face-up method may exist together.

The semiconductor chips other than the core chip CC0 placed on the top layer among the semiconductor chips, that is, the core chips CC1 to CC3 and the interface chip IF are provided with large numbers of penetrating electrodes TSV (Through Substrate Via) each passing through a silicon substrate. TSV may be called penetration electrodes, penetration vias, through-electirode, or through-vias. In areas that overlap with each of the penetrating electrodes TSV in planar view seen from a stacking direction, top-surface bumps FB are provided on the principal-surface sides of the chips, and back-surface bumps BB are provided on the back-surface sides of the chips. The back-surface bumps BB of a semiconductor chip placed on a lower layer are bonded to the top-surface bumps FB of a semiconductor chip placed on an upper layer. In this manner, the semiconductor chips that are adjacent to each other in the vertical direction are electrically connected.

According to the present embodiment, the reason why no penetrating electrode TSV is provided on the top-layer core chip CC0 is because there is no need to form a bump electrode on the back-surface side of the core chip CC0 as the chips are stacked by the face-down method. If no penetrating electrode TSV is provided on the top-layer core chip CC0 as described above, the top-layer core chip CC0 can be made thicker than the other core chips CC1 to CC3 to increase the mechanical strength of the core chip CC0. However, according to the present invention, penetrating electrodes TSV may be provided on the top-layer core chip CC0. In this case, all the core chips CC0 to CC3 can be produced by the same process.

The core chips CC0 to CC3 are semiconductor chips made by removing the so-called frontend section, which serves as an interface with the outside, from circuit blocks contained in a typical SDRAM (Synchronous Dynamic Random Access Memory) that operates alone. In other words, the core chips CC0 to CC3 are memory chips on which only circuit blocks belonging to the backend section are integrated. The circuit blocks contained in the frontend section include a parallel-to-serial conversion circuit which performs parallel-to-serial conversion of input/output data between a memory cell array and a data input/output terminal, a DLL (Delay Locked Loop) circuit which controls an input/output timing of data, and the like.

Meanwhile, the interface chip IF is a semiconductor chip on which only circuit blocks of the frontend section are integrated, among circuit blocks contained in a typical SDRAM that operates alone. The interface chip IF functions as a common frontend section for the four core chips CC0 to CC3. All accesses from the outside are conducted through the interface chip IF, and inputting and outputting of data are performed through the interface chip IF.

The interposer IP is a circuit board made of resin. On a back surface IPb thereof, a plurality of external terminals (solder balls) SB are formed. The interposer IP ensures the mechanical strength of the semiconductor device 10 and functions as a rewiring substrate to expand an electrode pitch. That is, substrate electrodes 91 that are formed on a top surface IPa of the interposer IP are led out to the back surface IPb via through-hole electrodes 92; rewiring layers 93 that are provided on the back surface IPb are designed to expand the pitch of the external terminals SB. The areas of the top surface IPa of the interposer IP where no substrate electrode 91 is formed are covered with resist 90a. The areas of the back surface IPb of the interposer IP where no external terminal SB is formed are covered with resist 90b. FIG. 1 shows only five external terminals SB. However, a large number of external terminals is actually provided. The layout of the external terminals SB is the same as that of a SDRAM determined by the standard. Accordingly, an external controller can handle the semiconductor device 10 as a SDRAM.

The gaps between the core chips CC0 to CC3 and interface chip IF stacked are filled with underfill 94. In this manner, the mechanical strength is ensured. The gap between the interposer IP and the interface chip IF is filled with NCP (Non-Conductive Paste) 95. The entire package is covered with mold resin 96. In this manner, each chip is physically protected.

The penetrating electrodes TSV provided in the core chips CC1 to CC3 and interface chip IF are arranged at a pitch P0 which is a processible minimum pitch or a slightly wider pitch than the processible minimum pitch, in order to curb an increase in the chip size. The value of the pitch P0 is for example about 40 to 50 μm. Meanwhile, the substrate electrodes 91 provided on the interposer IP are arranged at a pitch P1 (>P0) which is a minimum pitch allowed according to a wiring rule of the interposer IP or a slightly wider pitch than the minimum pitch. The value of the pitch P1 is for example about 75 to 150 μm. Although not specifically limited, it is preferable to set to P1=P0×2. In FIG. 1, each of the core chips CC1 to CC3 and interface chip IF has eight penetrating electrodes TSV arranged in lines T1 to T8 and the interface chip IF has six top-surface bumps FB arranged in lines T1 and T8 to T12. However, greater numbers of penetrating electrodes TSV and top-surface bumps FB are actually provided. As shown in FIG. 1, while some of the top-surface bumps FB provided on the interface chip IF are bonded to the substrate electrodes 91 on the interposer IP, the other top-surface bumps FB provided on the interface chip IF are not bonded to the substrate electrodes 91 on the interposer IP.

Most of the penetrating electrodes TSV provided on the core chips CC1 to CC3 are connected to the top-surface bumps FE and back-surface bumps BB that are provided at the same locations in planar view. In the present embodiment, the penetrating electrodes of such a kind are represented by penetrating electrodes TSV1. All the penetrating electrodes TSV1 belonging to lines T1 to T8 shown in FIG. 1 are penetrating electrodes TSV1.

On the other hand, most of the penetrating electrodes TSV provided on the interface chip IF are connected to the back-surface bumps BB that are provided at the same locations in planar view, but not connected to the top-surface bumps FE that are provided at the same locations in planar view. In the present embodiment, the penetrating electrodes of such a kind are represented by penetrating electrodes TSV2. In FIG. 1, the penetrating electrodes TSV corresponding to lines T2 to T7 of the penetrating electrodes TSV provided on the interface chip IF are the penetrating electrodes TSV2.

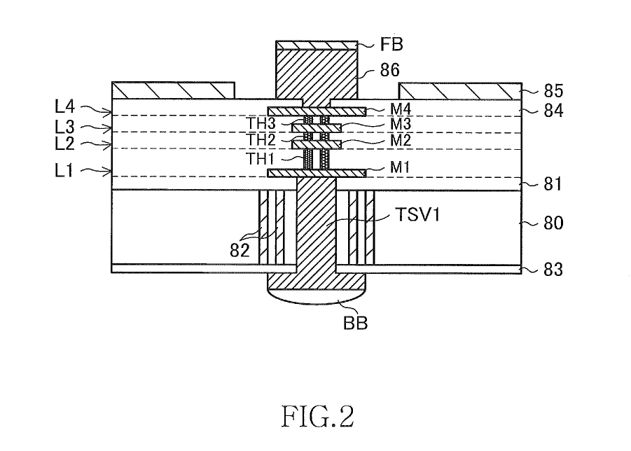

As shown in FIG. 2, the penetrating electrode TSV1 is so provided as to pass through a silicon substrate 80, an interlayer insulation film 81 which is provided on a top surface of the silicon substrate 80, and a passivation film 83 which is provided on a back surface of the silicon substrate 80. Although not specifically limited, the penetrating electrode TSV1 is made of Cu (copper). The top surface of the silicon substrate 80 (the upper surface in FIG. 2) serves as a device formation surface on which devices such as transistors are formed. Around the penetrating electrode TSV1, insulation rings 82 are provided to insulate the penetrating electrode TSV1 from a transistor region. In the example shown in FIG. 2, two insulation rings 82 are provided to reduce capacitance between the penetrating electrode TSV1 and the silicon substrate 80. Incidentally, one insulation ring 82, instead of two, may be provided.

An end portion of the penetrating electrode TSV1 that is closer to the back surface of the silicon substrate 80 is covered with a back-surface bump BB. As shown in FIG. 1, the back-surface bumps BB provided on the core chips CC1 to CC3 are in contact with the top-surface bumps FB provided on upper-layer core chips CC0 to CC2, respectively. the back-surface bumps BB provided on the interface chip IF are in contact with the top-surface bumps FB provided on the core chip CC3. Although not specifically limited, the back-surface bumps BB are made of SnAg solder covering the surfaces of the penetrating electrodes TSV1.

On the top surface of the silicon substrate 80, insulation films as many as five layers are formed. The above-mentioned interlayer insulation film 81 is one of the insulation films. The topmost layer is a passivation film 84. On the top surface of each of the layers except for the passivation film 84, wiring layers L1 to L4 are formed, respectively, in order from the nearest to the top surface of the silicon substrate 80. The wiring layers L1 to L4 are configured to include pads M1 to M4, respectively. The pad M1 of them is in contact with an end portion of the penetrating electrode TSV1 that is closer to the top surface of the silicon substrate 80. In each of the layers except for the above-mentioned interlayer insulation film 81 and the passivation film 84, a plurality of through-hole electrodes TH1 to TH3, respectively, in order from the nearest to the top surface of the silicon substrate 80. The pads M1 to M4 are connected each other by the through-hole electrodes TH1 to TH3.

The top-surface bump FE is connected to the pad M4 through a pillar portion 86 which penetrates through the passivation film 84. Therefore, the top-surface bump FB is connected to an end portion of the penetrating electrode TSV1 via the pillar portion 86, the pads M1 to M4, and the through-hole electrodes TH1 to TH3. As shown in FIG. 1, the top-surface bumps FB provided on the core chips CC1 to CC3 are in contact with the back-surface bumps BB provided on the lower-layer core chips CC2 and CC3 and the interface chips IF, respectively. The top-surface bumps FB provided on the interface chip IF are in contact with the substrate electrodes 91 on the interposer IP. Although not specifically limited, the top-surface bumps FB include a pillar portion 86 that is made of Cu (copper). A surface of the pillar portion 86 includes a stacking structure of Ni (nickel) and Au (gold). The diameter of the top-surface bumps FB and back-surface bumps BB is about 20 μm.

A top surface of the passivation film 84 except a region where the top-surface bump FE is formed is covered with a polyimide film 85. Incidentally, the connection to internal circuits not shown in the diagram is realized via internal wires (not shown), which are led out from the pads M1 to M3 provided in the wiring layers L1 to L3.

In that manner, the penetrating electrodes TSV1 are connected to the top-surface bumps FE and back-surface bumps BB that are provided at the same locations in planar view with respect to the same chip.

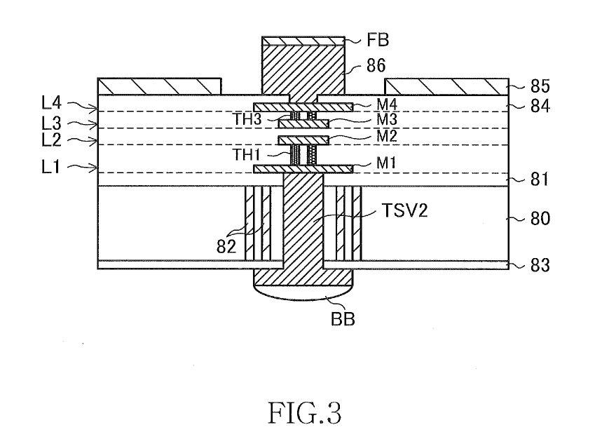

In contrast to this, with respect to the penetrating electrodes TSV2, as shown in FIG. 3, the through-hole electrodes TH2 connecting the pad M2 and the pad M3 provided at the same location in planar view is not provided. Therefore, the top-surface bumps FB and back-surface bumps BB that are provided at the same locations in planar view are not short-circuited. For the rest, the penetrating electrodes TSV1 and the penetrating electrodes TSV2 have the same structure.

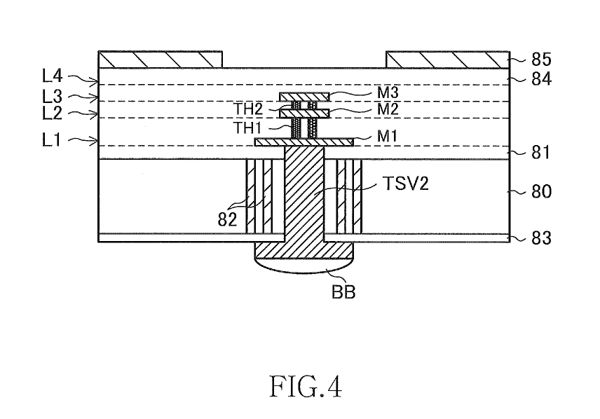

Here, the top-surface bumps FB of the penetrating electrodes TSV2 corresponding to lines T2 to T7 shown in FIG. 1 are not connected to the substrate electrodes 91 provided on the interposer IP. In such a case, not providing the top-surface bumps FB as shown in FIG. 4 is allowed.

The penetrating electrodes TSV2 provided on the interface chip IF, as shown in lines T2 to T7 of FIG. 1, constitute signal paths each of which is connected to the interface chip IF and the core chips CC0 to CC3 in common, in conjunction with the penetrating electrodes TSV1 provided on each of the core chips CC1 to CC3. The signals which the interface chip IF outputs via the signal paths are input into the core chips CC0 to CC3 in common. The signals which each of the core chips CC0 to CC3 outputs via the signal paths are subjected to a Wired-OR operation before being input into the interface chip IF.

On the other hand, the penetrating electrodes TSV1 provided on the interface chip IF, as shown in lines T1 to T8 of FIG. 1, also constitute signal paths each of which is connected to the interface chip IF and the core chips CC0 to CC3 in common, in conjunction with the penetrating electrodes TSV1 provided on each of the core chips CC1 to CC3. The signal paths are connected to the external terminals SB and are used mainly for supplying power supply potential.

Although not shown in FIG. 1, the penetrating electrodes TSV2 having a structure shown in FIG. 3 are also used in the core chips CC1 to CC3. The penetrating electrodes TSV2 provided on the core chips CC1 to CC3 are used to sequentially transfer predetermined information to the internal circuits (not shown) provided on each of the core chips CC0 to CC3, and to input unique information. The information includes chip address information, defective chip information, and the like.

Furthermore, on the interface chip IF, top-surface bumps FBa on which penetrating electrodes TSV are not provided at the same plane positions are provided, too. In FIG. 1, the top-surface bumps FBa are shown in Lines T9 to T12.

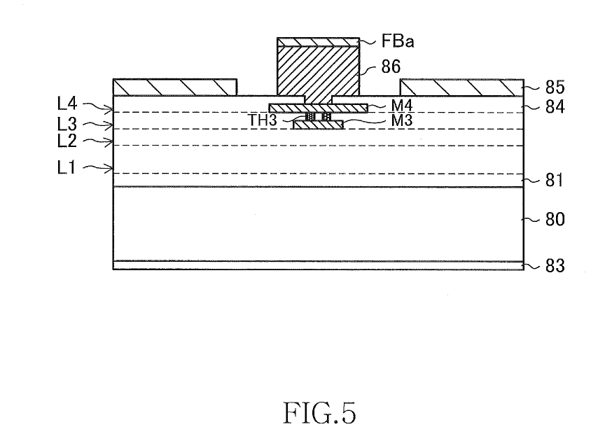

Turning to FIG. 5, the top-surface bump FBa provided on the interface chip IF is connected to the pads M4 and M3. Below the pads M4 and M3, the pads M2 and M1, the penetrating electrodes TSV, and the back-surface bump BB are not provided. The pads M4 and M3 are connected to logic circuits and other circuits in the interface chip IF, which are not shown in the diagram.

The above has described the configuration of the semiconductor device 10. The following describes the specific circuit configuration of the semiconductor device 10.

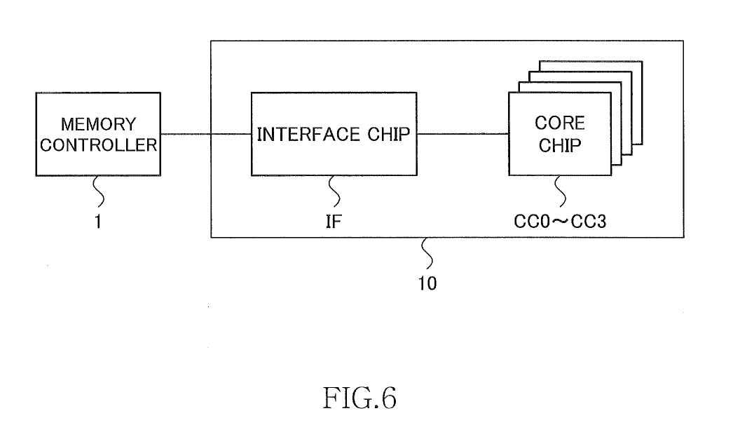

As shown in FIG. 6, the memory controller 1 is connected to each of the core chips CC0 to CC3 via the interface chip IF. Between the memory controller 1 and the semiconductor device 10, the above-described write leveling and read leveling are carried out. Between the interface chip IF and each of the core chips CC0 to CC3, timing adjustment of inputting and outputting of data, which is associated with the present invention, is performed.

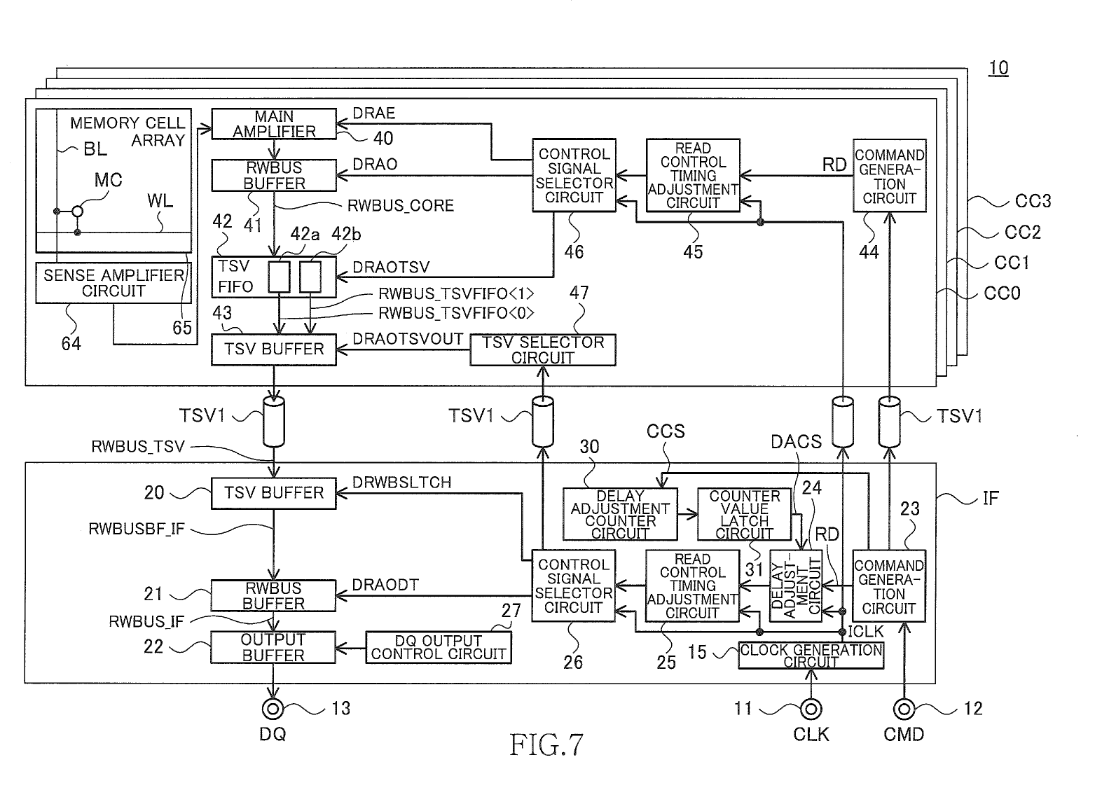

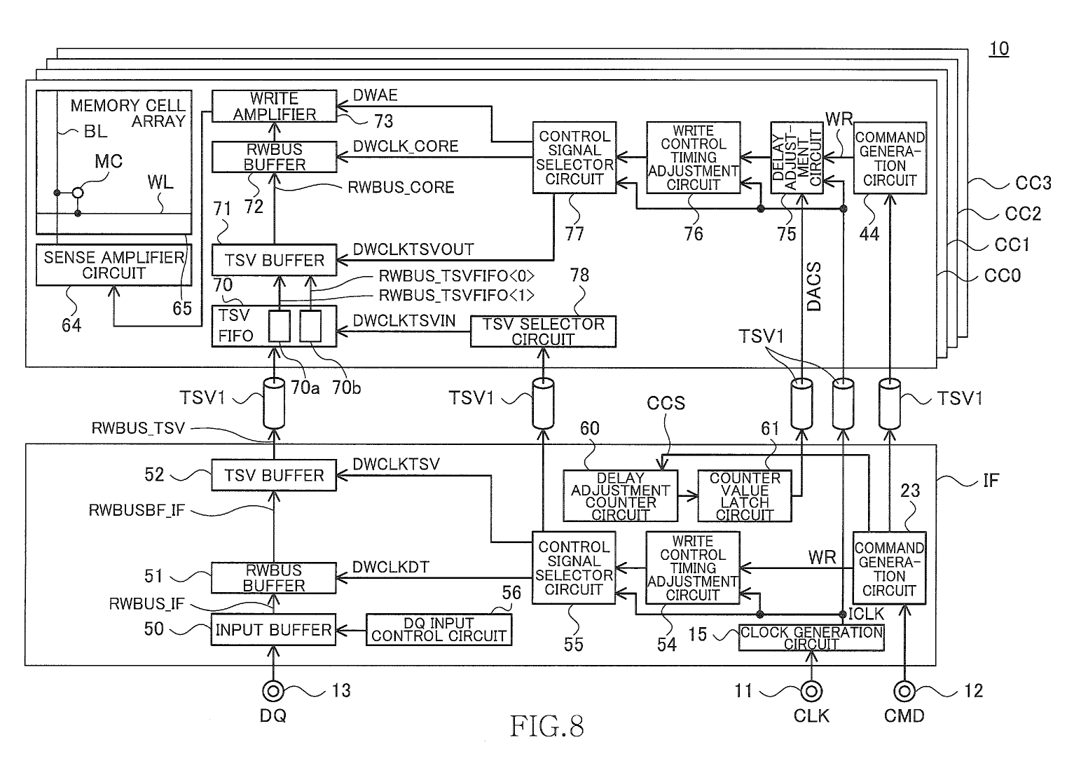

As shown in FIGS. 7 and 8, the external terminals provided in the interposer IP include clock terminals 11, command terminals 12, and data input/output terminals 13. Other terminals, such as address terminals, data strobe terminals, calibration terminals, and power-supply terminals, are also provided, but are not shown in the diagrams. Of the external terminals described above, all the external terminals except the power-supply terminal are connected to internal circuits in the interface chip IF, and are not connected directly to internal circuits in the core chips CC0 to CC3.

The clock terminal 11 is a terminal to which an external clock signal CLK is supplied. The supplied external clock signal CLK is supplied to a clock generation circuit 15. The clock generation circuit 15 is a circuit that generates an internal clock signal ICLK. The generated internal clock signal ICLK is supplied to various circuit blocks in the interface chip IF and core chips CC0 to CC3.

The command terminal 12 is a terminal to which command signals CMD are supplied: The command signals CMD include a row address strobe signal, a column address strobe signal, a write enable signal, a chip select signal, and a clock enable signal. The command signals CMD are supplied to a command generation circuit 23 of the interface chip IF and to a command generation circuit 44 of each of the core chips CC0 to CC3. To the command generation circuits 44, the command signals CMD are supplied from the command generation circuit 23 via the penetrating electrodes TSV1.

The command generation circuits 23 and 44 are circuits that generate various internal commands by decoding the command signals CMD input from the command terminal 12. The command signals CMD include a read command, write command, and MRS (Mode register Set) command. When the command signal CMD indicates a read command, the command generation circuits 23 and 44 each generate an internal read command RD. The internal read command RD generated by the command generation circuit 23 is supplied to a read control timing adjustment circuit 25 provided in the interface chip IF via a delay adjustment circuit 24. The internal read command RD generated by the command generation circuit 44 is supplied to a read control timing adjustment circuit 45 in the same core chip. When the command signal CMD indicates a write command, the command generation circuits 23 and 44 each generate an internal write command WR. The internal write command WR generated by the command generation circuit 23 is supplied to a write control timing adjustment circuit 54 provided in the interface chip IF. The internal write command WR generated by the command generation circuit 44 is supplied to a write control timing adjustment circuit 76 in the same core chip via a delay adjustment circuit 75.

The read control timing adjustment circuits 25 and 45 shown in FIG. 7 are circuits that generate various control signals in accordance with the internal read command RD (in accordance with a timing at which the read command is supplied to the command terminal 12). The control signals generated by the read control timing adjustment circuit 25 include a control signal DRAOTSVOUT, a control signal DRWBSLTCH, and a control signal DRAODT, as shown in FIG. 7. The control signals generated by the read control timing adjustment circuit 45 include a control signal DRAE, a control signal DRAO, and a control signal DRAOTSV.

The control signals DRAE, DRAO, and DRAOTSV generated by the read control timing adjustment circuit 45 each are supplied by a control signal selector circuit 46 to a main amplifier 40, RWBUS buffer 41, and TSVFIFO 42 in the same core chips. Of the control signals generated by the read control timing adjustment circuit 25, the control signals DRWBSLTCH and DRAODT each are supplied by a control signal selector circuit 26 to a TSV buffer 20 and RWBUS buffer 21 in the interface chip IF. The control signal DRAOTSVOUT is transmitted to a TSV selector circuit 47 in each of the core chips CC0 to CC3 via the control signal selector circuit 26 and the penetrating electrode TSV1. Then, the control signal DRAOTSVOUT is supplied by the TSV selector circuit 47 to a TSV buffer 43.

The write control timing adjustment circuits 54 and 76 shown in FIG. 8 are circuits that generate various control signals in accordance with the internal write command (in accordance with a timing at which the write command is supplied to the command terminal 12). The control signals generated by the write control timing adjustment circuit 54 include a control signal DWCLKDT, a control signal DWCLKTSV, and a control signal DWCLKTSVIN. The control signals generated by the write control timing adjustment circuit 76 include a control signal DWCLKTSVOUT, a control signal DWCLK_CORE, and a control signal DWAE.

Of the control signals generated by the write control timing adjustment circuit 54, the control signals DWCLKDT and DWCLKTSV each are supplied by a control signal selector circuit 55 to a RWBUS buffer 51 and a TSV buffer 52 in the interface chip IF. The control signal DWCLKTSVIN is transmitted to a TSV selector circuit 78 of each of the core chips CC0 to CC3 via the control signal selector circuit 55 and the penetrating electrode TSV1. Then, the control signal DWCLKTSVIN is supplied by the TSV selector circuit 78 to a TSVFIFO 70. The control signals DWCLKTSVOUT, DWCLK_CORE, and DWAE generated by the write control timing adjustment circuit 76 each are supplied by a control signal selector circuit 77 to a TSV buffer 71, RWBUS buffer 72, and write amplifier 73 in the same core chip.

The data input/output terminal 13 is a terminal for inputting and outputting of the read data DQ or write data DQ. For the read data DQ, as shown in FIG. 7, the data input/output terminal 13 is connected to an output buffer 22. The read data DQ that are read from a memory cell array 65 of each of the core chips CC0 to CC3 are supplied to the interface chip IF via signal paths including the penetrating electrode TSV1. Moreover, the read data DQ pass through the output buffer 22 before being output to the outside from the data input/output terminal 13. The operation timing of the output buffer 22 is controlled by a timing signal from a DQ output control circuit 27. For the write data DQ, as shown in FIG. 8, the data input/output terminal 13 is connected to an input buffer 50. The write data DQ that are input from the outside are supplied to the RWBUS buffer 51 via the input buffer 50. Then, the write data DQ pass through signal paths containing the penetrating electrode TSV1 before being supplied to each of the core chips CC0 to CC3. The operation timing of the input buffer 50 is controlled by a timing signal from a DQ input control circuit 56. Incidentally, only one data input/output terminal 13 is shown in FIGS. 7 and B. However, the semiconductor device 10 actually includes a plurality of data input/output terminals 13. The output buffer 22, the input buffer 50, and each of the circuits described later are provided for each of a plurality of the data input/output terminals 13.

The write data DQ are input in a burst mode into each of the data input/output terminals 13 by eight bits. Usually, the burst-mode inputting is performed twice in a row during one cycle. Accordingly, to each of the data input/output terminals 13, 16-bit write data DQ are supplied in a serial manner during one cycle. The input buffer 50 converts the 16-bit data, which are supplied as described above, into parallel data of four lines, which are then supplied to the RWBUS buffer 51.

The read data DQ are supplied from a RWBUS buffer 21 to the output buffer 22 as parallel data of four lines. In each line, four-bit data are contained. The output buffer 22 converts the parallel data of four lines into 16-bit serial data, which are then output in a burst mode from the data input/output terminal 13 by eight bits.

The following describes a read operation and write operation in the semiconductor device 10 in detail with reference to an operation timing chart of each signal.

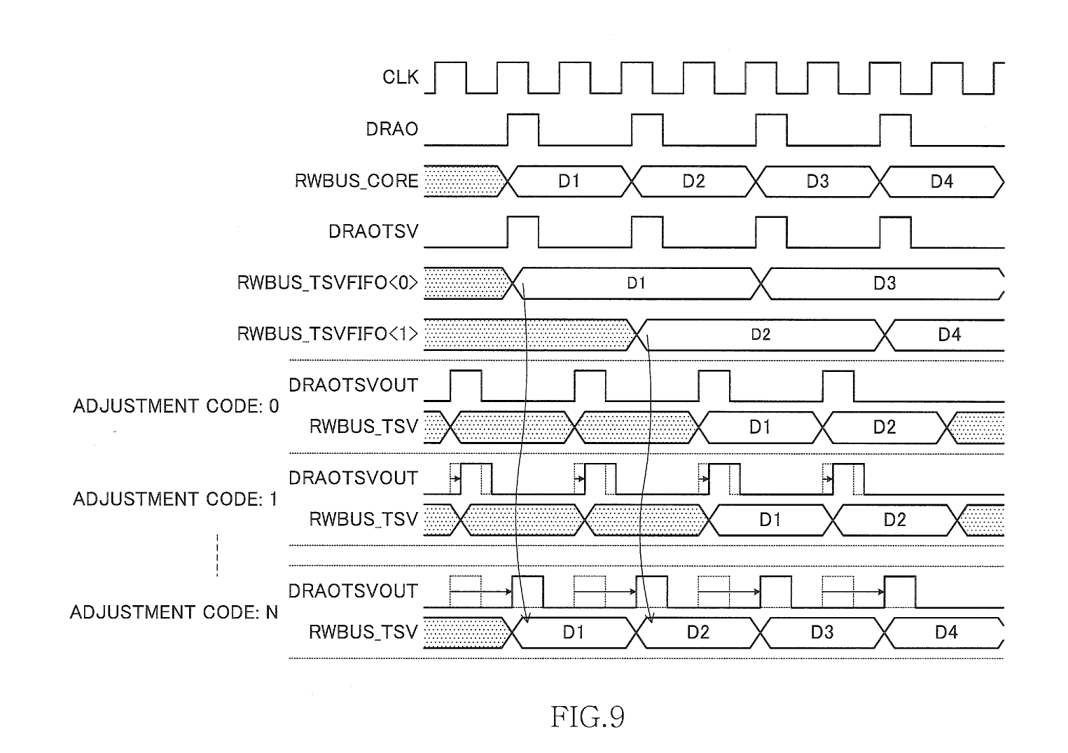

First, the configuration of the semiconductor device 10 that pertains to the read operation is explained in detail with reference to FIGS. 7 and 9.

For the read operation, in the interface chip IF (first semiconductor chip), the TSV buffer 20, the RWBUS buffer 21, and the output buffer 22 are provided as shown in FIG. 7. In each of the core chips CC0 to CC3 (second semiconductor chips), the main amplifier 40, the RWBUS buffer 41, the TSVFIFO 42 (or an output circuit that outputs data held in the second semiconductor chips), and the TSV buffer 43 (or an input circuit that captures data output from the output circuit) are provided. In each of the core chips CC0 to CC3, a sense amplifier circuit 64 and a memory cell array 65 are also provided.

The memory cell array 65 is made up of a plurality of word lines WL and bit lines BL that cross each other, and memory cells MC that are disposed at intersection points of the lines (In FIG. 7 and subsequent diagrams, only one word line WL, one bit line BL, and one memory cell MC are shown). The word lines WL are selected by a row-system control circuit (not shown) based on a row address supplied from the outside to the address terminal. The bit lines BL are connected to corresponding sense amplifiers in the sense amplifier circuit 64. The sense amplifiers are selected by a column-system control circuit (not shown) based on a column address supplied from the outside to the address terminal.

The read data DQ that are read from the memory cell array 65 pass through the main amplifier 40 and the RWBUS buffer 41 before being supplied to the TSVFIFO 42. The operation timings of the main amplifier 40 and the RWBUS buffer 41 are controlled by control signals DRAE and DRAO, respectively.

Read data sets D1 to D4 shown in FIG. 9 are one line of the parallel data of four lines (16-bit read data DQ) read from the memory cell array 65. The data RWBUS_CORE shown in FIG. 9 are output data of the RWBUS buffer 41. As shown in FIG. 9, the read data sets D1 to D4 are output with a duration of two clocks in a serial manner from the RWBUS buffer 41.

The TSVFIFO 42 is so configured as to capture the data RWBUS_CORE output from the RWBUS buffer 41 at a time when the control signal DRAOTSV (third control signal) is activated. Incidentally, as described above, the control signal DRAOTSV is a control signal that the read control timing adjustment circuit 45 (second timing adjustment circuit) generates based on the internal read command RD (second command) supplied from the command generation circuit 44 (second command generation circuit). As shown in FIG. 7, the TSVFIFO 42 includes two holding circuits 42a and 42b, which hold the captured data RWBUS_CORE in a parallel manner.

The holding circuit 42a is so configured as to capture the data RWBUS_CORE at timings when odd-numbered active sections of the control signal DRAOTSV whose active sections intermittently arrives is arriving. As a result, the holding circuit 42a sequentially holds the odd-numbered read data sets DQ (read data sets D1 and D3) among a plurality of read data sets DQ that are output in a serial manner from the RWBUS buffer 41. The holding circuit 42b is so configured as to capture the data RWBUS_CORE at timings when even-numbered active sections of the control signal DRAOTSV whose active sections intermittently arrives is arriving. As a result, the holding circuit 42b sequentially holds the even-numbered read data sets DQ (read data sets D2 and D4) among a plurality of read data sets DQ that are output in a serial manner from the RWBUS buffer 41. The data RWBUS_TSVFIFO<0> and data RWBUS_TSVFIFO<1> shown in FIG. 9 are data held by the holding circuits 42a and 42b, respectively. As shown in FIG. 9, the holding circuits 42a and 42b each hold the corresponding data for a period of time worth four clocks.

The TSV buffer 43 is a circuit that sequentially takes out a plurality of read data sets DQ from the two holding circuits 42a and 42b, and outputs the read data sets DQ to a core chip-side end portion of the penetrating electrode TSV1. The timing at which the TSV buffer 43 captures the data RWBUS_TSVFIFO<0> and the data RWBUS_TSVFIFO<1> is controlled by the control signal DRAOTSVOUT (first control signal). In this manner, the TSVFIFO 42 and the TSV buffer 43 make up a FIFO circuit whose input is in synchronization with the control signal DRAOTSV, and whose output is in synchronization with the control signal DDAOTSVOUT.

In this case, the control signal DRAOTSVOUT is a signal that is supplied from the interface chip IF, and represents a timing at which the read data DQ are captured by the interface chip IF. Meanwhile, the control signal DRAOTSV is generated inside the core chips. Therefore, the breakdown of synchronization is more likely to occur between the control signal DRAOTSV and the control signal DRAOTSVOUT than between the control signals that are generated in the same chip. To cope with the breakdown of synchronization, the semiconductor device 10 includes the TSVFIFO 42 and the delay adjustment circuit 24. The TSVFIFO 42 is a circuit that works for the case where the control signal DRAOTSVOUT lags behind the control signal DRAOTSV. Since the TSVFIFO 42 has the two holding circuits 42a and 42b, the TSVFIFO 42 is able to hold the read data DQ for a period of time (four clocks) that is twice as long as a conventional timing margin (two clocks). As a result, even if the control signal DRAOTSVOUT is delayed to a certain degree, the TSV buffer 43 can properly acquire the read data DQ. The delay adjustment circuit 24 is a circuit that works for the case where the control signal DRAOTSVOUT is ahead of the control signal DRAOTSV. The delay adjustment circuit 24 will be described later in detail.

The read data DQ that are output by the TSV buffer 43 to the core chip-side end portion of the penetrating electrode TSV1 are captured by the TSV buffer 20. Then, the read data DQ pass through the RWBUS buffer 21 and the output buffer 22 before being output to the external memory controller 1 (FIG. 6) from the data input/output terminal 13. The operation timings of the TSV buffer 20 and the RWBUS buffer 21 are controlled by the control signals DRWBSLTCH and DRAOUT, respectively. Both the control signals DRWBSLTCH and DRAOUT are control signals generated by the read control timing adjustment circuit 25 inside the interface chip IF. Therefore, the control signals DRWBSLTCH and DRAOUT are properly in synchronization with the control signal DRAOTSVOUT. As a result, the TSV buffer 20 and the RWBUS buffer 21 properly can capture the read data DQ at any time.

The following describes the functionality of the delay adjustment circuit 24 in detail.

The delay adjustment circuit 24 is a circuit that controls a timing at which the read control timing adjustment circuit 25 generates each control signal. This functionality is realized by delaying a timing at which the internal read command RD (first internal command) generated by the command generation circuit 23 (first command generation circuit) is supplied to the read control timing adjustment circuit 25 (first timing adjustment circuit). The semiconductor device 10 includes a delay adjustment counter circuit 30 and a counter value latch circuit 31, which are associated with the delay adjustment circuit 24. An amount of delay of the internal read command RD in the delay adjustment circuit 24 is set by the circuits 30 and 31. More specifically, the delay adjustment counter circuit 30 has a function of increasing a counter value in accordance with a counter control signal CCS supplied from the command generation circuit 23. Incidentally, the command generation circuit 23 is so configured as to generate the counter control signal CCS in response to the supply of the MRS command to the command terminal 12. The counter value latch circuit 31 is a circuit that latches the counter value of the delay adjustment counter circuit 30. The counter value latch circuit 31 also includes a fuse circuit (storage circuit) that contains a plurality of fuse elements, and is so configured as to store the counter value permanently by controlling how a plurality of the fuse elements are cut by means of a laser or the like. The counter value that is stored in the counter value latch circuit 31 is supplied as a delay adjustment code signal DACS to the delay adjustment circuit 24, thereby defining the amount of delay of the internal read command RD.

The “adjustment code: 0,” “adjustment code: 1,” and “adjustment code: N” shown in FIG. 9 represent the cases where the delay adjustment code signals DACS are 0, 1, and N, respectively. The value of the delay adjustment code signal DACS represents the amount of delay of the internal read command RD in the delay adjustment circuit 24. FIG. 9 shows an example in which the control signal DRAOTSVOUT is ahead of the control signal DRAOTSV when the delay adjustment code signal DACS is 0. In the example, the TSV buffer 43 fails to capture the read data DQ; for the signal RWBUS_TSV that is output from the TSV buffer 43, the previous-cycle output signal of the TSVFIFO 42 is set.

According to the present embodiment, an external tester is used at a testing stage before shipment to carry out a process of setting the optimal delay adjustment code signal DACS in the semiconductor device 10. More specifically, first as an initial state, predetermined data are written into the memory cell array 65. The writing may be performed by a test circuit (not shown) when each core chip is part of a wafer (or before the core chips are stacked). Moreover, in the delay adjustment counter circuit 30, the counter value is set to 0 as an initial value. During the setting process, first an act command and a row address are input into the command terminal 12 and an address terminal (not shown), respectively; then, a read command and a column address are input into the command terminal 12 and the address terminal, respectively. As a result, from the data input/output terminal 13, the read data DQ are output. The external tester confirms whether or not the correct data have been output. If the read data DQ output are not correct, a MRS command is input into the command terminal 12, and the command generation circuit 23 therefore generates a counter control signal CCS, thereby increasing the counter value of the delay adjustment counter circuit 30 by one. After that, the above process is repeated until the correct read data DQ are output. After the correct read data DQ are output, the counter value at that time is written into the fuse circuit in the counter value latch circuit 31 by means of a laser or the like. In this manner, the process of setting the optimal delay adjustment code signal DACS is completed.

In the example shown in FIG. 9, the delay adjustment code signal DACS starts to increase from zero at a rate of one. When the delay adjustment code signal DACS reaches N, the TSV buffer 43 can properly capture the read data DQ. As a result, the delay adjustment code signal DACS N is written into the fuse circuit inside the counter value latch circuit 31.

As described above, the semiconductor device 10 makes a determination as to whether or not the interface chip IF has properly captured the read data DQ. Based on the result thereof, the semiconductor device 10 sets the delay adjustment code signal DACS in the counter value latch circuit 31. In this manner, the semiconductor device 10 can accurately adjust the timing at which the interface chip IF captures the read data DQ.

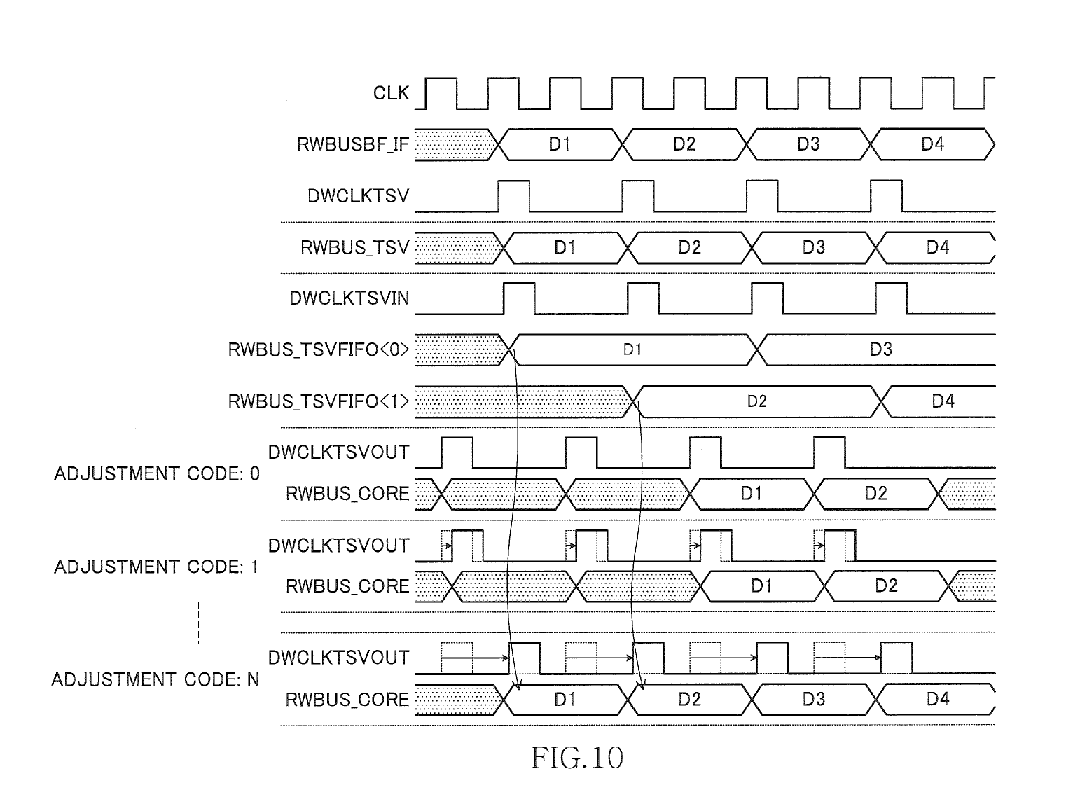

Next, the configuration of the semiconductor device 10 that pertains to the write operation is explained in detail with reference to FIGS. 8 and 10.

For the write operation, in the interface chip IF (second semiconductor chip), the input buffer 50, the RWBUS buffer 51, and the TSV buffer 52 (output buffer) are provided as shown in FIG. 8. In each of the core chips CC0 to CC3 (first semiconductor chip), the TSVFIFO 70 (or an output circuit that outputs data held in the second semiconductor chip), the TSV buffer 71 (an input circuit, or input buffer, that captures data output from the output circuit), the RWBUS buffer 72, and the write amplifier 73 are provided.

The write data DQ that are input from the data input/output terminal 13 pass through the input buffer 50, the RWBUS buffer 51, and the TSV buffer 52 before being supplied to an interface chip-side end portion of the penetrating electrode TSV1. During the process, the input buffer 50, the RWBUS buffer 51, and the TSV buffer 52 each temporarily hold the write data DQ. The operation timings of the RWBUS buffer 51 and the TSV buffer 52 are controlled by the control signals DWCLKDT and DWCLKTSV, respectively.

The write data sets D1 to D4 shown in FIG. 10 are one line of the parallel data of four lines (16-bit write data DQ) output from the input buffer 50. The data RWBUSBF_IF and data RWBUS_TSV shown in FIG. 10 are output data of the RWBUS buffer 51 and the TSV buffer 52, respectively. As shown in FIG. 10, the write data sets D1 to D4 are output with a duration of two clocks in a serial manner from the RWBUS buffer 51.

The TSV buffer 52 is so configured as to capture the data RVBUSBF_IF at a time when the control signal DWCLKTSV (second control signal) is activated, and then output the captured data RVBUSBF_IF to the penetrating electrode TSV1 until the next time the control signal DWCLKTSV becomes activated (Data RWBUS_TSV). As shown in FIG. 10, the control signal DWCLKTSV is so controlled as to be activated at intervals of two clocks. Therefore, the TSV buffer 52 sequentially captures the write data sets D1 to D4, and sequentially outputs the write data sets D1 to D4 to the penetrating electrode TSV1 with a duration of two clocks.

The TSVFIFO 70 is connected to the penetrating electrode TSV1. The TSVFIFO 70 is so configured as to capture the data RWBUS_TSV that appears at the core chip-side end portion of the penetrating electrode TSV1 at a time when the control signal DWCLKTSVIN (third control signal) is activated. Incidentally, as described above, the control signal DWCLKTSVIN is a control signal that the write control timing adjustment circuit 54 (second timing adjustment circuit) generates based on the internal write command WR (second command) supplied from the command generation circuit 23 (second command generation circuit). As shown in FIG. 8, the TSVFIFO 70 includes the two holding circuits 70a and 70b, which hold the captured data RWBUS_TSV in a parallel manner.

The functionality of the holding circuits 70a and 70b are the same as that of the above-described holding circuits 42a and 42b. That is, the holding circuit 70a is so configured as to capture the data RWBUS_TSV at timings when odd-numbered active sections of the control signal DWCLKTSVIN whose active sections intermittently arrives is arriving. As a result, the holding circuit 70a sequentially holds the odd-numbered write data sets DQ (write data sets D1 and D3) among a plurality of write data sets DQ that are supplied in a serial manner from the interface chip IF. The holding circuit 70b is so configured as to capture the data RWBUS_TSV at a time when even-numbered active sections of control the signal DWCLKTSVIN whose active sections intermittently arrives is arriving. As a result, the holding circuit 70b sequentially holds the even-numbered write data sets DQ (write data sets D2 and D4) among a plurality of write data sets DQ that are supplied in a serial manner from the interface chip IF. The data RWBUS_TSVFIFO<0> and data RWBUS_TSVFIFO<1> shown in FIG. 10 are data held by the holding circuits 70a and 70b, respectively. As shown in FIG. 10, the holding circuits 70a and 70b each hold the corresponding data for a period of time worth four clocks.

Incidentally, the control signal DWCLKTSVIN is control signal generated by the write control timing adjustment circuit 54 in the interface chip IF. Therefore, the control signal DWCLKTSVIN is properly in synchronization with the control signal DWCLKTSV and the control signal DWCLKTSVIN. As a result, the TSVFIFO 70 properly can acquire the write data DQ at any time.

The TSV buffer 71 is an input buffer circuit that sequentially takes out a plurality of write data sets DQ from the two holding circuits 70a and 70b, and outputs the write data sets DQ to the memory cell array 65 via the RWBUS buffer 72, the write amplifier 73, and the sense amplifier circuit 64. The timings at which the TSV buffer 71 captures the data RWBUS_TSVFIFO<0> and the data RWBUS_TSVFIFO<1> are controlled by the control signal DWCLKTSVOUT (first control signal).

The control signal DWCLKTSVOUT is a signal that is generated in the core chips, and represents a timing at which the core chips capture the write data DQ. Meanwhile, the control signal DWCLKTSVIN is generated inside the interface chip IF. Therefore, the breakdown of synchronization is more likely to occur between the control signal DWCLKTSVIN and the control signal DWCLKTSVOUT than between the control signals that are generated in the same chip. This relation is the same as the above-described relation between the control signal DRAOTSV and the control signal DRAOTSVOUT. The following circuits are provided to cope with the breakdown of synchronization during the write operation: the TSVFIFO 70 and the delay adjustment circuit 75. The TSVFIFO 70 is a circuit that works for the case where the control signal DWCLKTSVOUT lags behind the control signal DWCLKTSVIN. Since the TSVFIFO 70 is provided, as in the case of the read operation, even if the control signal DWCLKTSVOUT is delayed to a certain degree, the TSV buffer 71 can properly acquire the write data DQ. The delay adjustment circuit 75 is a circuit that works for the case where the control signal DWCLKTSVOUT is ahead of the control signal DWCLKTSVIN. The delay adjustment circuit 75 will be described later in detail.

The advantageous effects brought about by the use of the TSVFIFO 70 will be described in more detail. Incidentally, the following description is similarly applied to the TSVFIFO 42 pertaining to the read operation.

If no TSVFIFO 70 is provided, the TSV buffer 71 can no longer properly capture the write data DQ at a time when the synchronization between the control signal DWCLKTSVOUT and the control signal DWCLKTSVIN breaks down and the difference therebetween exceeds two clocks. The reason is that the duration of the write data DQ that are output from the interface chip IF to the core chips is equal to two clocks as indicated by the data RWBUS_TSV in FIG. 10. If the allowable range for synchronization breakdown is referred to as a timing margin, the timing margin is equal to two clocks if no TSVFIFO 70 is provided. On the other hand, in the semiconductor device 10, the TSVFIFO 70 having the two holding circuits 70a and 70b is provided. Therefore, the timing margin is so extended as to be equal to four clocks.

The data RWBUS_CORE shown in FIG. 10 is data output from the TSV buffer 71. As shown in FIG. 10, the control signal DWCLKTSVOUT is controlled by the write control timing adjustment circuit 76 in such a way that the control signal DWCLKTSVOUT is alternately activated and inactivated at intervals of two clocks. The TSV buffer 71 is so configured as to capture the data RWBUS_TSVFIFO<0> (or data that are held by the holding circuit 70a) for an odd-numbered section, out of the active sections of the control signal DWCLKTSVOUT that is controlled as described above; and to capture the data RWBUS_TSVFIFO<0> (or data that are held by the holding circuit 70b) for an even-numbered section. As a result, as shown in FIG. 10, the TSV buffer 71 sequentially captures the write data sets D1 to D4, and outputs the write data sets D1 to D4 to the subsequent RWBUS buffer 72 with a width of two clocks. In this manner, the TSVFIFO 70 and the TSV buffer 71 make up a FIFO circuit whose input is in synchronization with the control signal DWCLKTSVIN, and whose output is in synchronization with the control signal DWCLKTSVOUT.

As described above, each of the holding circuits 70a and 70b holds the corresponding data for a period of time worth four clocks. Accordingly, as shown in FIG. 10, even if the synchronization between the control signal DWCLKTSVOUT and the control signal DWCLKTSV breaks down, and the difference therebetween becomes greater than or equal to two clocks, the correct write data DQ are held by the holding circuits 70a and 70b at a time when the TSV buffer 71 is about to capture the write data DQ as long as the difference is less than or equal to four clocks. Therefore, the TSV buffer 71 can properly capture the write data DQ.

In that manner, on the core chips, the two holding circuits 70a and 70b are provided. Therefore, at the entrance of the core chips, the write data DQ can be held for a longer period of time (four clocks) than the duration (two clocks) of the write data that are output from the interface chip IF to the core chips. Accordingly, the timing margin, or the allowable range for synchronization breakdown between the control signal DWCLKTSV and the control signal DWCLKTSVOUT, can be extended so as to be equal to four clocks.

The write data DQ that are output from the TSV buffer 71 pass through the RWBUS buffer 72, the write amplifier 73, and the sense amplifier circuit 64 before being written into memory cells inside the memory cell array 65. The operation timings of the RWBUS buffer 72 and the write amplifier 73 are controlled by the control signals DWCLK_CORE and DWAE, respectively. Both the control signals DWCLK_CORE and DWAE are control signals generated by the write control timing adjustment circuit 76 inside the core chips. Therefore, the control signals DWCLK_CORE and DWAE are properly in synchronization with the control signal DWCLKTSVOUT. Thus, the RWBUS buffer 72 and the write amplifier 73 can properly acquire the write data DQ at any time.

The following describes the functionality of the delay adjustment circuit 75 in detail.

The delay adjustment circuit 75 is a circuit that controls a timing at which the write control timing adjustment circuit 76 generates each control signal. This functionality is realized by delaying a timing at which the internal write command WR (first internal command) generated by the command generation circuit 44 (first command generation circuit) is supplied to the write control timing adjustment circuit 76 (first timing adjustment circuit). The semiconductor device 10 includes a delay adjustment counter circuit 60 and a counter value latch circuit 61, which are associated with the delay adjustment circuit 75. An amount of delay of the internal write command WR in the delay adjustment circuit 75 is set by the circuits 60 and 61. Incidentally, unlike the delay adjustment circuit 75, the delay adjustment counter circuit 60 and the counter value latch circuit 61 are provided in the interface chip IF.

The detailed functionality of the delay adjustment counter circuit 60 and the counter value latch circuit 61, as well as a process of setting the delay adjustment code signal DACS, is the same as that of the above-described delay adjustment counter circuit 30 and the counter value latch circuit 31. More specifically, the delay adjustment counter circuit 60 has a function of increasing or decreasing a counter value in accordance with a counter control signal CCS supplied from the command generation circuit 23. The counter value latch circuit 61 is a circuit that latches the counter value of the delay adjustment counter circuit 60. The counter value latch circuit 61 also includes a fuse circuit (storage circuit) that contains a plurality of fuse elements, and is so configured as to store the counter value permanently by controlling how a plurality of the fuse elements are cut by means of a laser or the like. The counter value that is stored in the counter value latch circuit 61 is supplied as a delay adjustment code signal DACS to the delay adjustment circuit 75, thereby defining the amount of delay of the internal write command WR. Incidentally, the counter value latch circuit 61 and the delay adjustment circuit 75 are provided in different chips. Therefore, the delay adjustment code signal DACS is transmitted from the counter value latch circuit 61 to the delay adjustment circuit 75 via a signal path that includes the penetrating electrode TSV1.

The “adjustment code: 0,” “adjustment code: 1,” and “adjustment code: N” shown in FIG. 10 represent the cases where the delay adjustment code signals DACS are 0, 1, and N, respectively. The value of the delay adjustment code signal DACS represents the amount of delay of the internal write command WR in the delay adjustment circuit 75. FIG. 10 shows an example in which the control signal DWCLKTSVOUT is ahead of the control signal DWCLKTSVIN when the delay adjustment code signal DACS is 0. In the example, the TSV buffer 71 fails to capture the write data DQ; for the signal RWBUS_CORE that is output from the TSV buffer 71, the previous-cycle output signal of the TSVFIFO 70 is set.

According to the present embodiment, as in the case of the read operation, an external tester is used for the write operation at a testing stage before shipment to carry out a process of setting the optimal delay adjustment code signal DACS in the semiconductor device 10. The setting process is performed with confirming by the read operation whether or not the write data DQ have been properly written. Therefore, it is preferred that the setting process be carried out after the setting process for the read operation is completed.

During the setting process, first an act command and a row address are input into the command terminal 12 and an address terminal (not shown), respectively; then, a write command, a column address, and write data DQ are input into the command terminal 12, the address terminal, and the data input/output terminal 13, respectively. After that, a read command and a column address are input into the command terminal 12 and the address terminal, respectively. As a result, the read data DQ are output from the data input/output terminal 13. The external tester confirms whether or not the read data DQ are equal to the write data DQ that are input in advance. If both are not equal, a MRS command is input into the command terminal 12, and the command generation circuit 23 therefore generates a counter control signal CCS, thereby increasing the counter value of the delay adjustment counter circuit 60 by one. After that, the above process is repeated until the read data DQ output become equal to the input write data DQ. After both become equal as a result, the counter value at that time is written into the fuse circuit in the counter value latch circuit 61 by means of a laser or the like. In this manner, the process of setting the optimal delay adjustment code signal DACS is completed.

In the example shown in FIG. 10, the delay adjustment code signal DACS starts to increase from zero at a rate of one. When the delay adjustment code signal DACS reaches N, the TSV buffer 71 can properly capture the write data DQ. As a result, the delay adjustment code signal DACS N is written into the fuse circuit inside the counter value latch circuit 61.

As described above, the semiconductor device 10 makes a determination as to whether or not the core chips CC0 to CC3 have properly captured the write data DQ. Based on the result thereof, the semiconductor device 10 sets the delay adjustment code signal DACS in the counter value latch circuit 61. In this manner, the semiconductor device 10 can accurately adjust the timing at which the core chips CC0 to CC3 capture the write data DQ.

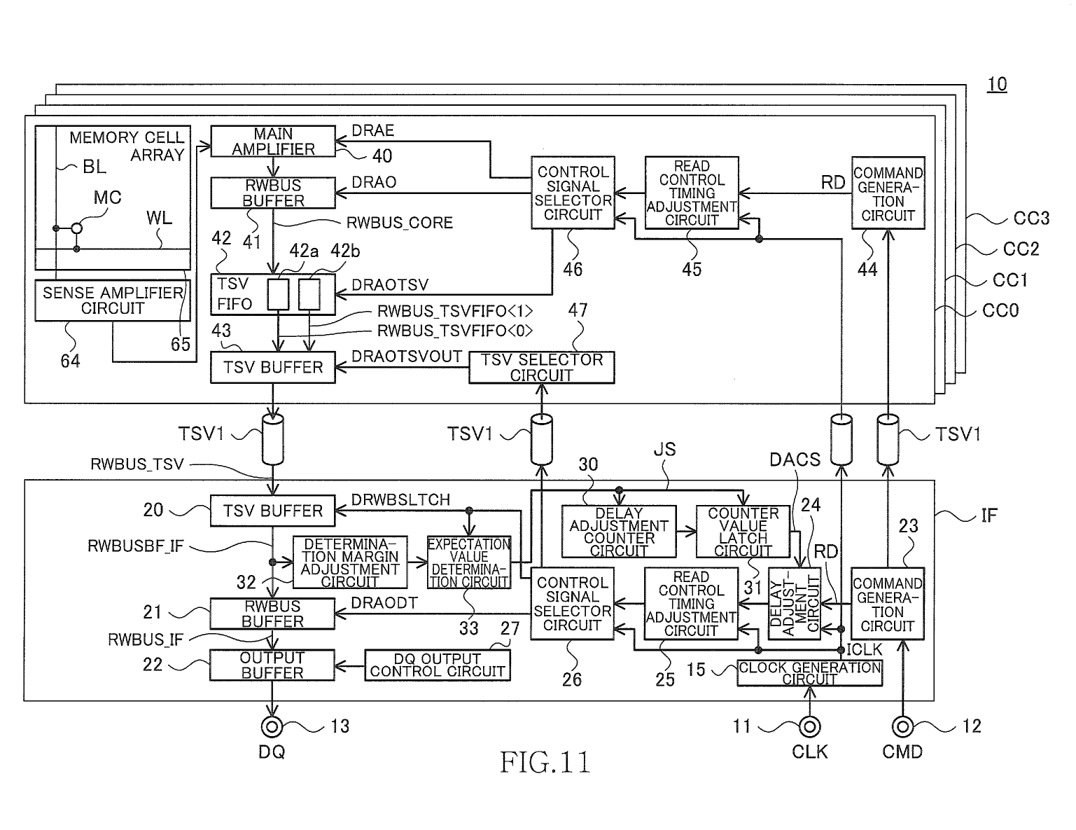

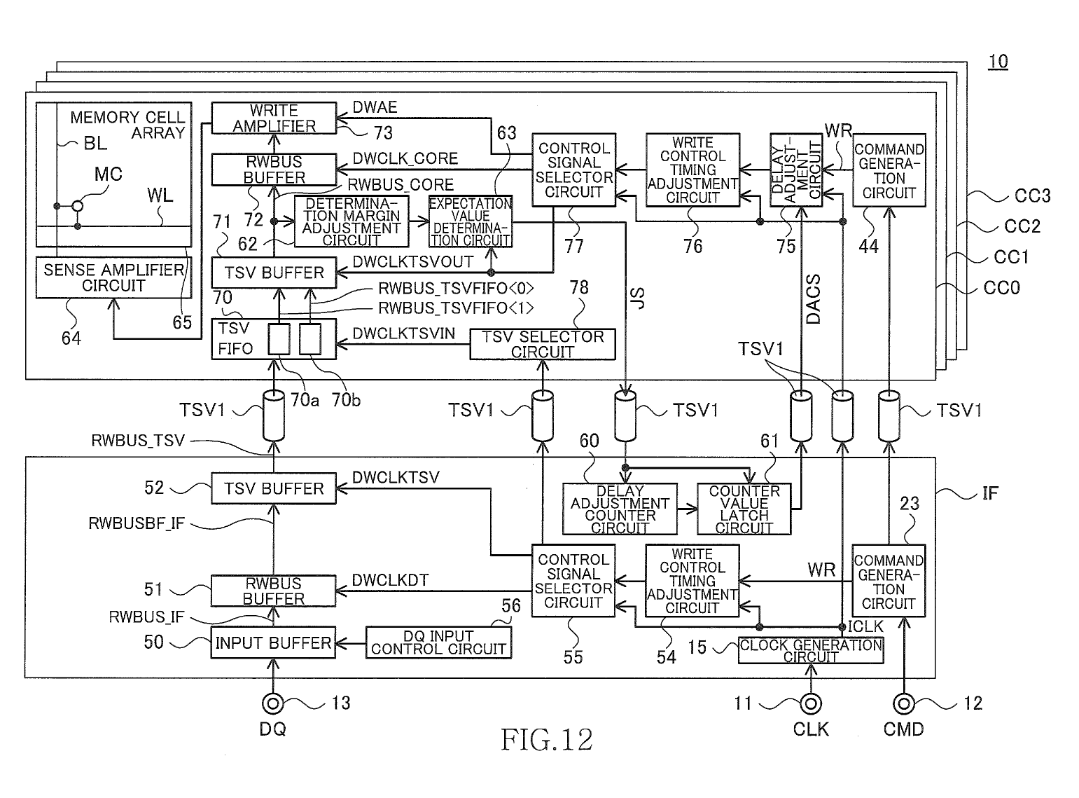

The semiconductor device 10 of the second embodiment is different from the semiconductor device 10 of the first embodiment shown in FIGS. 7 to 10 in that the semiconductor device 10 of the present embodiment includes a determination margin adjustment circuit 32 and an expectation value determination circuit 33 (both of which are shown in FIG. 11), and a determination margin adjustment circuit 62 and an expectation value determination circuit 63 (both of which are shown in FIG. 12). The other components are the same as those of the semiconductor device 10 of the first embodiment. The determination margin adjustment circuit 32 and the expectation value determination circuit 33 are provided in the interface chip IF, and the determination margin adjustment circuit 62 and the expectation value determination circuit 63 are provided in each of the core chips CC0 to CC3. The above circuits are provided to make the above-described process of setting the delay adjustment code signal DACS semiautomatic. The process of determining whether or not the data are correct, which is carried out by the external tester in the case of the first embodiment, is carried out by the expectation value determination circuits 33 and 63 in the case of the present embodiment. The following description focuses on the differences between the semiconductor device 10 of the present embodiment and the semiconductor device 10 of first embodiment.

As for the read operation (FIG. 11), the determination margin adjustment circuit 32 is a circuit that delays the data RWBUSBF_IF, which is output from the TSV buffer 20, by a predetermined amount of delay and then supplies the data RWBUSBF_IF to the expectation value determination circuit 33. The amount of delay is set by an external tester in advance in the determination margin adjustment circuit 32. An expectation value (or a value of the read data DQ output from the TSV buffer 20 if the data are properly captured) of the read data DQ is stored in the expectation value determination circuit 33. The expectation value determination circuit 33 compares the expectation value with the data RWBUSBF_IF supplied from the determination margin adjustment circuit 32, and generates a determination signal JS based on the comparison result. The operation timing of the expectation value determination circuit 33 is controlled by the control signal DRWBSLTCH, which is also supplied to the TSV buffer 20. The determination signal JS is supplied to the delay adjustment counter circuit 30 and the counter value latch circuit 31.

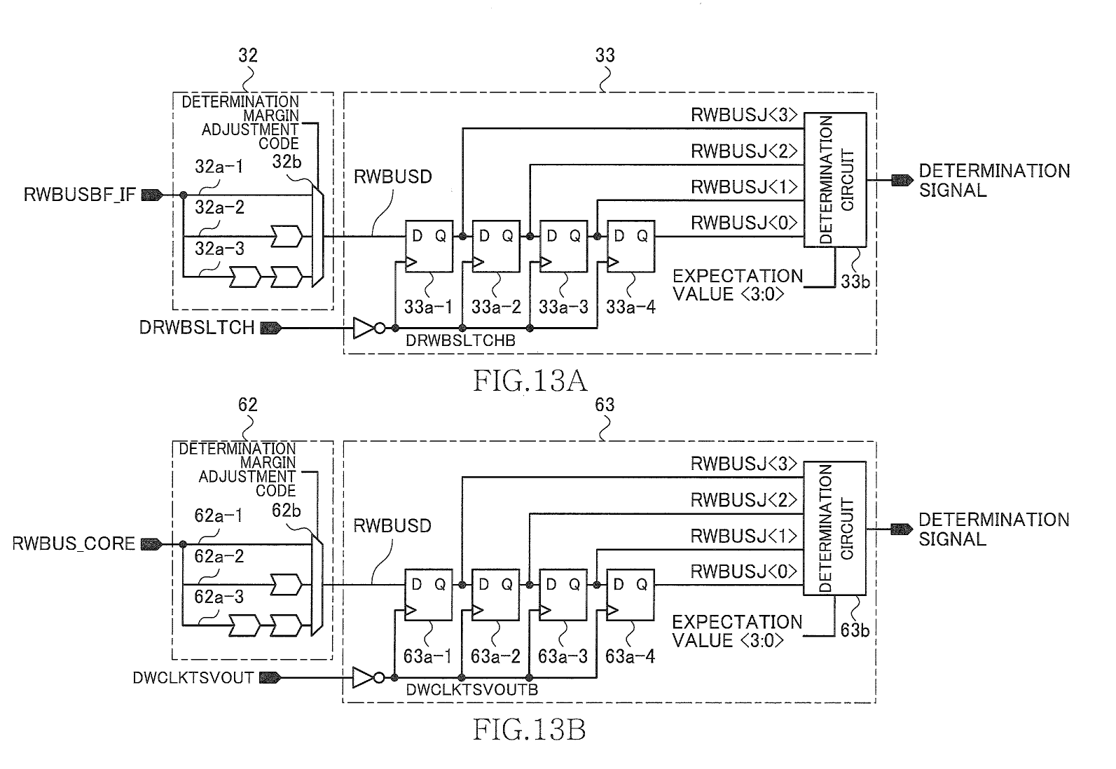

As shown in FIG. 13A, the determination margin adjustment circuit 32 is so configured as to include a plurality of paths 32a-1 to 32a-3, which are different in the amount of delay; and a selector 32b. To input terminals of the paths 32a-1 to 32a-3, the data RWBUSBF_IF are supplied. Output terminals of the paths 32a-1 to 32a-3 are connected to input terminals of the selector 32b. An output terminal of the selector 32b serves as an output terminal of the determination margin adjustment circuit 32. To the selector 32b, a determination margin adjustment code is supplied from an external tester. The determination margin adjustment code is used to select one of a plurality of the paths 32a-1 to 32a-3. The selector 32 connects only a path selected by the determination margin adjustment code to the output terminal of the determination margin adjustment circuit 32. An output signal of the determination margin adjustment circuit 32 is supplied as a signal RWBUSD to the expectation value determination circuit 33.

The expectation value determination circuit 33 is so configured as to include D-type flip-flops 33a-1 to 33a-4, which are connected in cascade; and a determination circuit 33b. The D-type flip-flops 33a-1 to 33a-4 each include an input terminal D, an output terminal Q, and a clock terminal. The D-type flip-flops 33a-1 to 33a-4 are so configured as to start outputting a signal supplied to the input terminal D from the output terminal Q at a timing when a signal supplied to the clock terminal becomes activated. To the clock terminals of the D-type flip-flops 33a-1 to 33a-4, an inverted signal DRWBSLTCHB of the control signal DRWBSLTCH is supplied in common. To the input terminal D of the first-stage D-type flip-flop 33a-1, the signal RWBUSD is supplied. Output signals of the D-type flip-flops 33a-1 to 33a-4 are supplied to the determination circuit 33b as data RWBUSJ<3> to <0>. Therefore, the four-bit read data DQ that are supplied in a serial manner as the signal RWBUSD are converted into the four-bit, parallel data RWBUSJ<3> to <0>, which are then supplied to the determination circuit 33b.

The determination circuit 33b has a function of comparing the data RWBUSJ<3> to <0> with the four-bit expectation value <3:0>, which is stored in advance in the expectation value determination circuit 33. The determination circuit 33b outputs a determination signal JS that indicates the comparison result to the delay adjustment counter circuit 30 and the counter value latch circuit 31, as shown in FIG. 11.

Returning to FIG. 11, the delay adjustment counter circuit 30 has a function of increasing the counter value by one in response to the determination signal JS that indicates “mismatch”. The counter value latch circuit 31 has a function of setting a counter value latched at that time in the fuse circuit in response to the determination signal JS that indicates “match”. The counter value that is set in the fuse circuit is later written into the fuse circuit by means of a laser or the like.

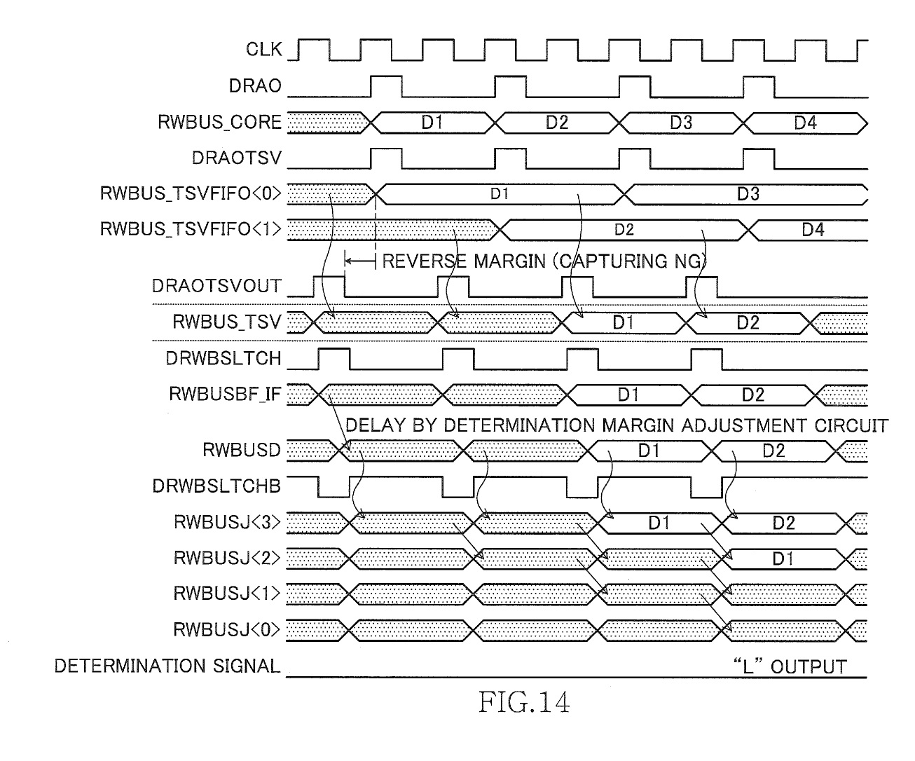

The following describes the flow of the process of setting the delay adjustment code signal DACS, which is executed by the above circuits, with reference to an example of an operation timing of each signal pertaining to the read operation shown in FIGS. 14, 15, and 16.

In FIGS. 14, 15, and 16, the signals shown above the signal RWBUS_TSV, as well as the signal RWBUS_TSV, are the same as those in the example shown in FIG. 9. The following description focuses on the differences between the present example and the example shown in FIG. 9.

The setting process is repeatedly carried out as the delay adjustment code signal DACS is incremented until the TSV buffer 43 is able to capture the read data DQ without fail.

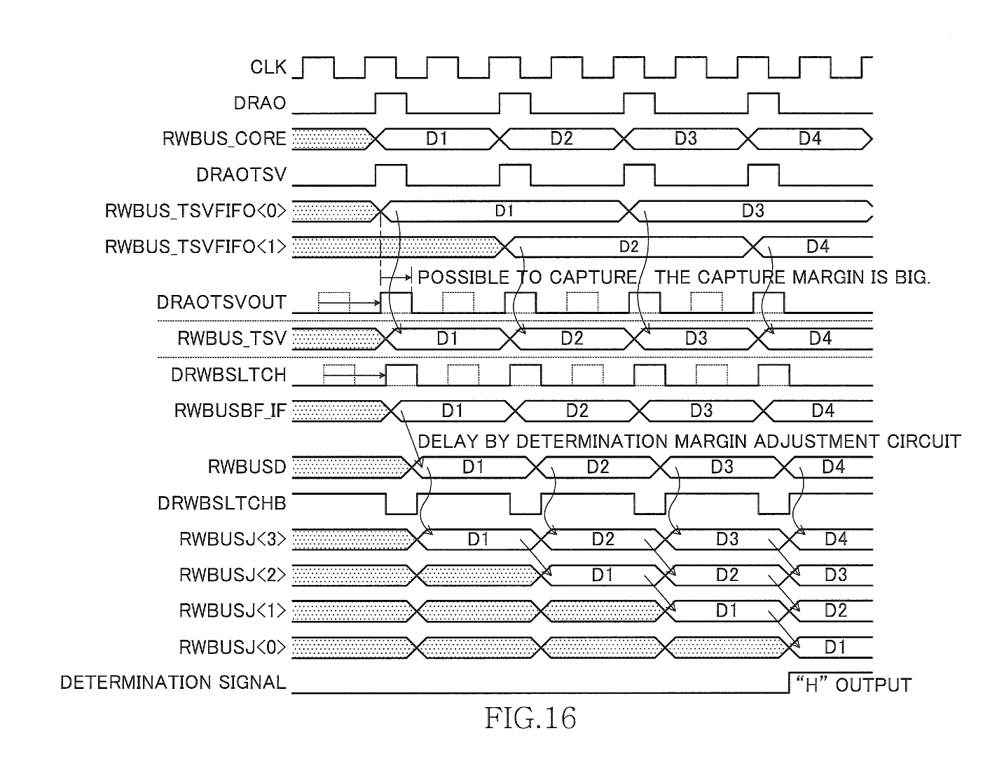

FIG. 16 shows a situation where the setting process is completed, i.e. a situation where the TSV buffer 43 is able to capture the read data DQ without fail. As shown in the example, when the TSV buffer 43 is able to capture the read data DQ without fail, data sets D4 to D1 are set for data RWBUSJ<3> to <0> that are input into the determination circuit 33b in such a way as to correspond to the last active section of one cycle that is identified by four active sections of the control signal DRWBSLTCH. The expectation value determination circuit 33 compares the data RWBUSJ<3> to <0> at that time with the expectation value <3:0>. In the case of FIG. 16, the data RWBUSJ<3> to <0> and the expectation value <3:0> are equal. Therefore, the expectation value determination circuit 33 sets the logical value of the determination signal JS to “High”, which indicates “match”. As a result, into the fuse circuit of the counter value latch circuit 31, the delay adjustment code signal DACS at that time is written.

FIG. 14 shows an example of the first of a series of setting processes that are repeatedly performed. In the example, it can be understood from the data RWBUS_TSV shown in FIG. 14 that the TSV buffer 43 (FIG. 11) has failed to capture the read data DQ. The reason is because the control signal DRAOTSVOUT is ahead of the control signal DRAOTSV (or because of the reverse margin). As a result, the logical value of the determination signal JS is “Low,” and the counter value of the delay adjustment counter circuit 30 is increased by one.

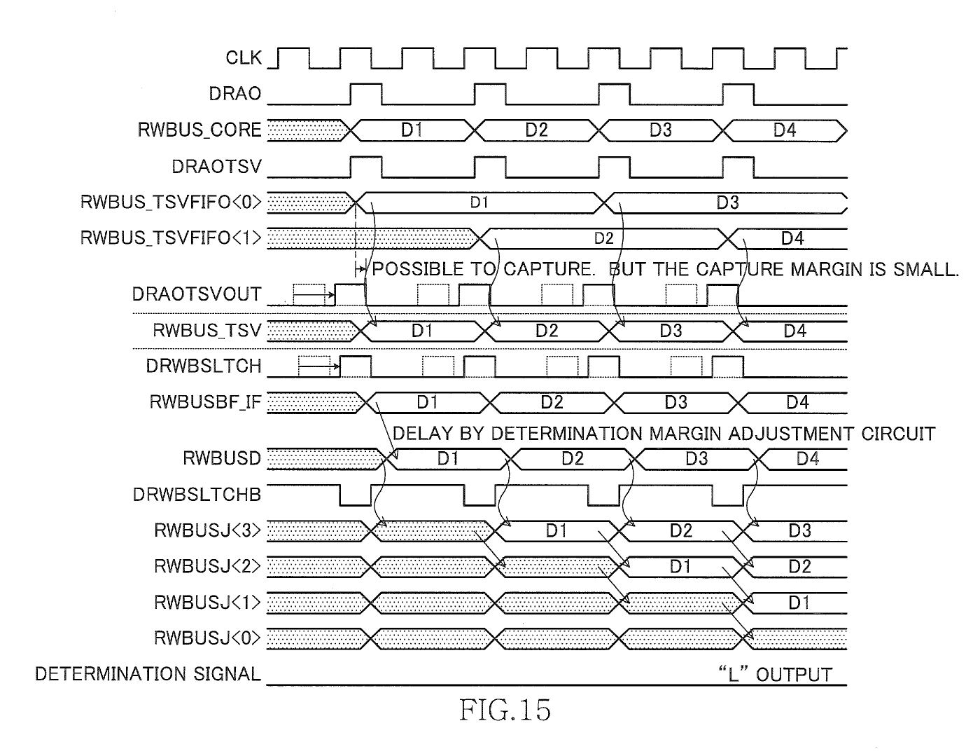

FIG. 15 shows an example in which the TSV buffer 43 becomes able to properly capture the read data DQ after several setting processes. However, in this case, the areas where the active periods of the control signal DRAOTSVOUT and the active sections of the output signal of the TSVFIFO 42 overlap with each other (or the capture margin of the read data DQ) are small. The possibility thus remains that the reverse margin could easily appear as the environment in which the semiconductor device 10 is used changes (or as the temperature, or the power-supply voltage supplied from the outside, changes). Therefore, it cannot be said that the above state enables “the TSV buffer 43 to capture the read data DQ without fail.” The semiconductor device 10 is configured so as not to settle the delay adjustment code signal DACS in the above state. More specifically, the above process is performed by the determination margin adjustment circuit 32, which will be described below in detail.

As described above, the determination margin adjustment circuit 32 is a circuit that delays a timing at which the data RWBUSBF_IF are supplied to the expectation value determination circuit 33. Since the timing is delayed, the read data DQ is slightly behind the inverted signal DRWBSLTCHB in entering the expectation value determination circuit 33, as indicated by the signal RWBUSD of FIG. 15. As a result, in the example of FIG. 15, at the first activation timing of the inverted signal DRWBSLTCHB, the data set D1 is not captured in the data RWBUSJ<3>. Finally, the logical value of the determination signal JS is “Low.” Therefore, the delay adjustment code signal DACS remains unsettled, and the counter value of the delay adjustment counter circuit 30 is increased by one. After that, the setting process continues until the situation shown in FIG. 16 arises.

The above has described the configuration for the read operation. The following describes the configuration for the write operation. The functionality of the determination margin adjustment circuit 62 and expectation value determination circuit 63 (FIG. 12) for the write operation is substantially the same as the functionality of the determination margin adjustment circuit 32 and expectation value determination circuit 33 (FIG. 11) for the read operation. Therefore, the same points will not be described arbitrarily.

The determination margin adjustment circuit 62 shown in FIG. 12 is a circuit that delays the data RWBUSBF_CORE, which are output from the TSV buffer 71, by a predetermined amount of delay and then supplies the data RWBUSBF_CORE to the expectation value determination circuit 63. The amount of delay is set by an external tester in advance in the determination margin adjustment circuit 62. An expectation value (or a value of the write data DQ output from the TSV buffer 71 if the data are properly captured) of the write data DQ is stored in the expectation value determination circuit 63. The expectation value determination circuit 63 compares the expectation value with the data RWBUSBF_CORE supplied from the determination margin adjustment circuit 62, and generates a determination signal JS based on the comparison result. The operation timing of the expectation value determination circuit 63 is controlled by the control signal DWCLKTSVOUT, which is also supplied to the TSV buffer 71. The determination signal JS is supplied to the delay adjustment counter circuit 60 and the counter value latch circuit 61 in the interface chip IF via a signal path that includes the penetrating electrode TSV1.

As shown in FIG. 13B, the determination margin adjustment circuit 62 is so configured as to include a plurality of paths 62a-1 to 62a-3, which are different in the amount of delay; and a selector 62b. To input terminals of the paths 62a-1 to 62a-3, the signal RWBUS_CORE are supplied in common. The expectation value determination circuit 63 is so configured as to include D-type flip-flops 63a-1 to 63a-4, which are connected in cascade; and a determination circuit 63b. To clock terminals of the D-type flip-flops 63a-1 to 63a-4, an inverted signal DWCLKTSVOUTB of the control signal DWCLKTSVOUT is supplied in common.

It can be understood from a comparison between FIGS. 13A and 13B that the internal configurations of the determination margin adjustment circuit 62 and expectation value determination circuit 63 are the same as those of the determination margin adjustment circuit 32 and expectation value determination circuit 33. Accordingly, the processes of the determination margin adjustment circuit 62 and expectation value determination circuit 63 are the same as those of the determination margin adjustment circuit 32 and expectation value determination circuit 33. Therefore, the processes will not be detailed again.

Returning to FIG. 12, the delay adjustment counter circuit 60 has a function of increasing the counter value by one in response to the determination signal JS that indicates “mismatch”. The counter value latch circuit 61 has a function of setting a counter value latched at that time in the fuse circuit in response to the determination signal JS that indicates “match”. The counter value that is set in the fuse circuit is later written into the fuse circuit by means of a laser or the like.

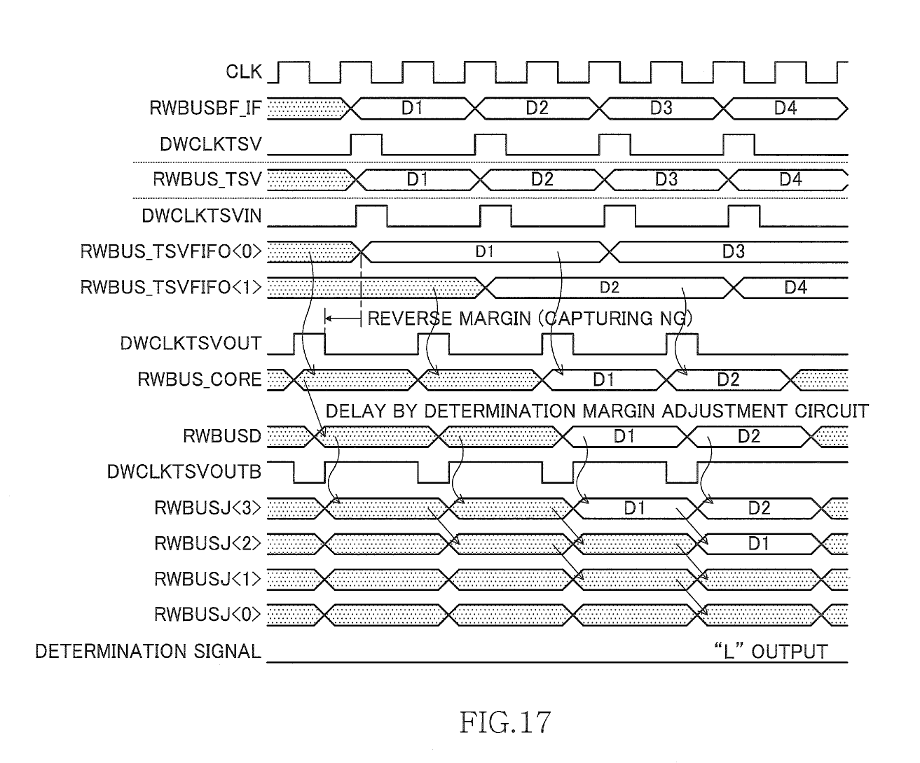

The following describes the flow of the process of setting the delay adjustment code signal DACS, which is executed by the above circuits, with reference to an example of an operation timing of each signal pertaining to the write operation shown in FIGS. 17, 18, and 19.

In FIGS. 17, 18, and 19, the signals shown above the signal RWBUS_CORE, as well as the signal RWBUS_CORE, are the same as those in the example shown in FIG. 10. The following description focuses on the differences between the present example and the example shown in FIG. 10.

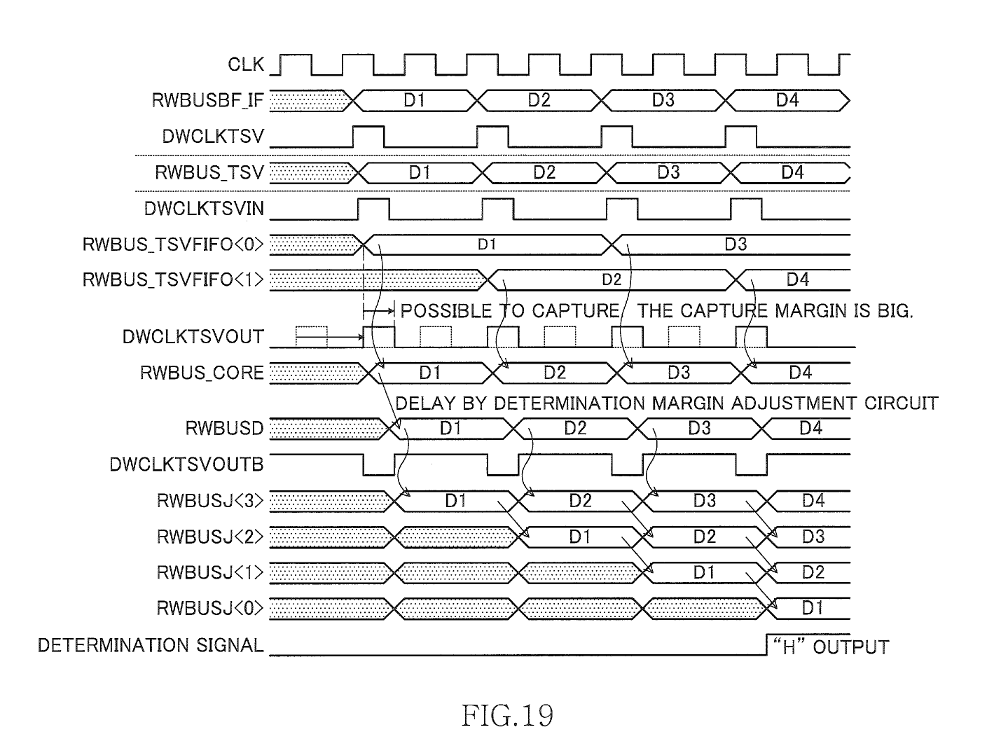

Even for the write operation, the setting process is repeatedly carried out as the delay adjustment code signal DACS is incremented until the TSV buffer 71 is able to capture the write data DQ without fail. FIG. 19 shows a situation where the setting process is completed, i.e. a situation where the TSV buffer 71 is able to capture the write data DQ without fail. As shown in the example, when the TSV buffer 71 is able to capture the write data DQ without fail, data sets D4 to D1 are set for data RWBUSJ<3> to <0> that are input into the determination circuit 63b in such a way as to correspond to the last active section of one cycle that is identified by four active sections of the control signal DWCLKTSVOUT. The expectation value determination circuit 63 compares the data RWBUSJ<3> to <0> at that time with the expectation value <3:0>. In the case of FIG. 19, the data RWBUSJ<3> to <0> and the expectation value <3:0> are equal. Therefore, the expectation value determination circuit 63 sets the logical value of the determination signal JS to “High”, which indicates “match”. As a result, into the fuse circuit of the counter value latch circuit 61, the delay adjustment code signal DACS at that time is written.

FIG. 17 shows an example of the first of a series of setting processes that are repeatedly performed. In the example, it can be understood from the data RWBUS_CORE shown in FIG. 17 that the TSV buffer 71 (FIG. 12) has failed to capture the write data DQ. The reason is because the control signal DWCLKTSVOUT is ahead of the control signal DWCLKTSVIN (or because of the reverse margin). As a result, the logical value of the determination signal JS is “Low,” and the counter value of the delay adjustment counter circuit 60 is increased by one.

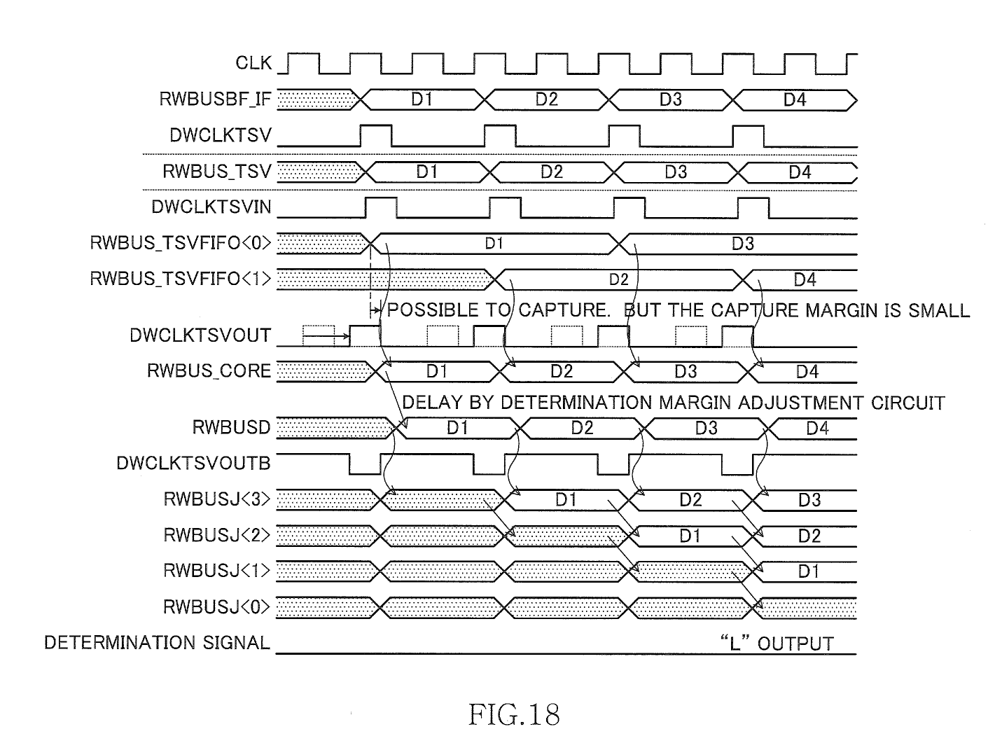

FIG. 18 shows an example in which the TSV buffer 71 becomes able to properly capture the write data DQ after several setting processes. However, in this case, the areas where the active periods of the control signal DWCLKTSVOUT and the active sections of the output signal of the TSVFIFO 70 overlap with each other (or the capture margin of the write data DQ) are small. The possibility thus remains that the reverse margin could easily appear as the environment in which the semiconductor device 10 is used changes (or as the temperature, or the power-supply voltage supplied from the outside, changes). Therefore, it cannot be said that the above state enables “the TSV buffer 71 to capture the write data DQ without fail.” The semiconductor device 10 is configured so as not to settle the delay adjustment code signal DACS in the above state. The above process is performed by the determination margin adjustment circuit 62, and the details thereof are the same as those of the determination margin adjustment circuit 32 for the read operation. Therefore, the detailed description will be omitted.

As a result of the process by the determination margin adjustment circuit 62, in the example shown in FIG. 18, at the first activation timing of the inverted signal DWCLKTSVOUTB, the data set D1 is not captured in the data RWBUSJ<3>, and the logical value of the determination signal JS is “Low.” As a result, the delay adjustment code signal DACS remains unsettled, and the counter value of the delay adjustment counter circuit 60 is increased by one. After that, the setting process continues until the situation shown in FIG. 19 arises.

As described above, the semiconductor device 10 of the present embodiment makes it possible to automatically perform the process of determining whether or not the data are correct for both the read operation and write operation. Also, since the determination margin adjustment circuits 32 and 62 are provided, it is possible to secure a wider capture margin of data.

Moreover, the semiconductor device 10 of the present embodiment is also effective in shortening the time required for a screening process after assembly. More specifically, in the screening process after assembly, a plurality of semiconductor devices 10 are tested at the same time. However, the value of the delay adjustment code signal DACS may vary for each semiconductor device 10. Moreover, the fuse elements are cut by first applying an address identifying a target fuse element from the address terminal, and then using a laser to cut the fuse element. Accordingly, according to the semiconductor device 10 of the first embodiment, an address signal needs to be individually input into each semiconductor device 10 before a fuse element is cut by laser. According to the semiconductor device 10 of the present embodiment, the counter value latch circuit 61 sets the counter value in the fuse circuit, thereby making it possible to omit the process of individually inputting the address signal into each semiconductor device 10. Therefore, the time required for the screening process after assembly can be shortened.

It is apparent that the present invention is not limited to the above embodiments, but may be modified and changed without departing from the scope and spirit of the invention.

For example, what is described in the above embodiments is an example in which the data are input and output in a burst mode in such a way that four bits are input and output at one time. The present invention also can be widely applied to the case where at least one bit of data is input and output.

According to the above embodiments, in each of the TSVFIFO 42 and 70, two holding circuits are provided. However, the number of holding circuits provided in the TSVFIFO 42 and 70 is not limited to two as long as a plurality of holding circuits are provided. In one example, if the number of holding circuits provided in the TSVFIFO 70 is n, the k^{th} (k is a value ranging from 1 to n) holding circuit is designed to capture the data RWBUS_TSV at a timing when the k+n×m^{th} active section (m is an integer greater than or equal to zero) of active sections of the control signal DWCLKTSVIN has arrived. As a result, each holding circuit becomes able to retain the captured write data DQ for a period of time worth 2n clocks. Thus, the timing margin can be so extended as to be equal to 2n clocks.

According to the above embodiments, for the read operation, both the TSVFIFO 42 and the delay adjustment circuit 24 are used to deal with the case where the control signal DRAOTSVOUT is behind, or ahead of, the control signal DRAOTSV. However, if the case where the control signal DRAOTSVOUT is behind the control signal DRAOTSV is not problematic, the TSVFIFO 42 may not be provided, and the data RWBUS_CORE may be received directly by the TSV buffer 43. If the case where the control signal DRAOTSVOUT is ahead of the control signal DRAOTSV is not problematic, the delay adjustment circuit 24 and a related circuit thereof may not be provided, and the internal read command RD generated by the command generation circuit 23 may be directly supplied to the read control timing adjustment circuit 25.

Similarly, according to the above embodiments, for the write operation, both the TSVFIFO 70 and the delay adjustment circuit 75 are used to deal with the case where the control signal DWCLKTSVOUT is behind, or ahead of, the control signal DWCLKTSVIN. However, if the case where the control signal DWCLKTSVOUT is behind the control signal DWCLKTSVIN is not problematic, the TSVFIFO 70 may not be provided, and the data RWBUS_TSV may be received directly by the TSV buffer 71. If the case where the control signal DWCLKTSVOUT is ahead of the control signal DWCLKTSVIN is not problematic, the delay adjustment circuit 75 and a related circuit thereof may not be provided, and the internal write command WR generated by the command generation circuit 44 may be directly supplied to the write control timing adjustment circuit 76.

What is claimed is:

1. A semiconductor device comprising:
a first semiconductor chip including:
a first timing adjustment circuit generating a first control signal based on a command; and
an output buffer outputting a plurality of data sets in a serial at a timing based on the first control signal; and
a second semiconductor chip including:
a plurality of holding circuits holding the data sets in parallel;
a second timing adjustment circuit generating a second control signal based on the command; and
an input buffer sequentially capturing the data sets supplied from the holding circuits based on the second control signal.

2. The semiconductor device as claimed in claim 1, wherein
the second semiconductor chip is a core chip including a memory cell array,
the first semiconductor chip is an interface chip controlling the core chip, and
the data sets are write data sets that are to be written into the memory cell array via the interface chip.

3. The semiconductor device as claimed in claim 1, wherein the second semiconductor chip further includes a delay adjustment circuit that adjusts a timing at which the second control signal is generated.

4. The semiconductor device as claimed in claim 3, wherein one of the first and second semiconductor chips further includes a storage circuit in which a delay amount of the delay adjustment circuit is stored.

5. The semiconductor device as claimed in claim 4, wherein the delay amount stored in the storage circuit is adjustable by a control signal supplied from outside.

6. The semiconductor device as claimed in claim 3, wherein the second semiconductor chip further includes a determination circuit that determining the data sets output from the input buffer.

7. The semiconductor device as claimed in claim 3, wherein the storage circuit includes a nonvolatile storage element.

8. The semiconductor device as claimed in claim 1, wherein the second semiconductor chip further includes:
a second timing adjustment circuit generating a third control signal that represents a timing at which the data sets are output from the first semiconductor chip in response to the command; and
an output circuit outputting the data sets based on the third control signal.

9. The semiconductor device as claimed in claim 1, wherein the first semiconductor chip and the second semiconductor chip are connected via a plurality of signal paths including penetrating electrodes that penetrating through at least one of the first and second semiconductor chips.

10. A semiconductor device comprising:
a first semiconductor chip including:
a holding circuit having a data input node, the holding circuit capturing and temporarily holding data appearing on the data input node in response to a first timing signal;
a buffer circuit coupled to the holding circuit, the buffer circuit outputting the data held by the holding circuit in response to a second timing signal;
a first timing circuit generating one of the first and second timing signals;
a second semiconductor chip includes a second timing circuit generating the other one of the first and second timing signals; and
a latch circuit holding a control data that are used to adjust a gap between a timing at which the first timing signal is brought to an active level and a timing at which the second timing signal is brought to an active level.

11. The semiconductor device as claimed in claim 10, wherein the holding circuit comprises a FIFO circuit that captures data in accordance with the first timing signal.

12. The semiconductor device as claimed in claim 10, wherein the latch circuit is provided in the second semiconductor chip.

13. The semiconductor device as claimed in claim 10, wherein the first semiconductor chip is stacked on the second semiconductor chip.

14. The semiconductor device as claimed in claim 10, further comprising a penetrating electrode provided on at least one of the first and second semiconductor chips.

15. The semiconductor device as claimed in claim 10, wherein
the first semiconductor chip is a core chip including a memory cell array, and
the second semiconductor chip is an interface chip controlling the core chip.

16. A semiconductor device comprising:
a first chip including a FIFO circuit connected to an input node thereof; and
a second chip supplying an input data to the input node of the FIFO circuit,
wherein the first and second chips are stacked to each other.

17. The semiconductor device as claimed in claim 16, further comprising a plurality of penetrating electrodes provided on at least one of the first and second chips,
wherein the input node is connected to at least one of the penetrating electrodes.

18. The semiconductor device as claimed in claim 16, wherein the FIFO circuit captures the input data in response to a first timing signal generated by the second chip.

19. The semiconductor device as claimed in claim 16, wherein the first chip further includes a buffer circuit connected to an output node of the FIFO circuit, the buffer circuit outputs data held by the FIFO circuit in response to a second timing signal generated by the first chip.

20. The semiconductor device as claimed in claim 16, wherein the first chip further includes another FIFO circuit connected to the input node, the another FIFO circuit is activated when outputting an output data to the second chip via the input node.
